(19) United States
(12) Patent Application Publication
(10) Pub. No.: US 2025/0306189 A1
(43) Pub. Date: Oct. 2, 2025

(54) METHOD FOR REDUCING CURRENT CONSUMED BY TOF SENSOR AND ELECTRONIC DEVICE SUPPORTING SAME

(71) Applicant: Samsung Electronics Co., Ltd., Suwon-si (KR)

(72) Inventors: Gwangho CHOI, Suwon-si (KR); Hanul MOON, Suwon-si (KR); Changyong SHIN, Suwon-si (KR); Daehan WI, Suwon-si (KR); Jeongseok LEE, Suwon-si (KR)

(21) Appl. No.: 19/236,433

(22) Filed: Jun. 12, 2025

Related U.S. Application Data
(63) Continuation of application No. PCT/KR2024/001826, filed on Feb. 7, 2024.

(30) Foreign Application Priority Data
Feb. 7, 2023 (KR) 10-2023-0016070
Feb. 28, 2023 (KR) 10-2023-0026862

(51) Int. Cl. G01S 7/497; G01S 7/481; G01S 7/484; G01S 7/4865; G01S 17/894

(52) U.S. Cl. CPC G01S 7/497; G01S 7/4814; G01S 7/484; G01S 7/4865; G01S 17/894

(57) ABSTRACT

An electronic deice is provided. The electronic device includes a camera module including a plurality of cameras, a time of flight (TOF) sensor, memory, comprising one or more storage media, storing instructions, and one or more processors communicatively coupled to the camera module, the TOF sensor, and the memory, wherein the instructions, when executed by the one or more processors individually or collectively, cause the electronic device to detect the operations of the camera module and the TOF sensor, identify at least one designated condition associated with setting the operation of the TOF sensor, determine whether to change the setting of the TOF sensor, on the basis of the designated condition, perform communication with the TOF sensor based on a first designated communication speed corresponding to a default setting when it is determined that the setting is not changed, change the setting of the TOF sensor from the default setting to a designated setting when it is determined that the setting is changed, perform communication with the TOF sensor based on a second designated communication speed adjusted in response to the change in the setting.

### CROSS-REFERENCE TO RELATED APPLICATION(S)

This application is a continuation application, claiming priority under 35 U.S.C. § 365(c), of an International application No. PCT/KR2024/001826, filed on Feb. 7, 2024, which is based on and claims the benefit of a Korean patent application number 10-2023-0016070, filed on Feb. 7, 2023, in the Korean Intellectual Property Office, and of a Korean patent application number 10-2023-0026862, filed on Feb. 28, 2023, in the Korean Intellectual Property Office, the disclosure of each of which is incorporated by reference herein in its entirety.

### BACKGROUND

### 1. Technical Field

The disclosure relates to a method for reducing current consumption due to an operation of a time of flight (TOF) sensor in an electronic device including the TOF sensor and an electronic device supporting the same.

### 2. Description of Related Art

With the development of digital technology, various types of electronic devices, such as smart phones, digital cameras, and/or wearable devices, are widely used. In order to support and increase the functions of these electronic devices, hardware and/or software parts of the electronic devices are continuously being developed.

Recently, with the increase in the use of image capturing functions using the electronic devices, various studies are being conducted to support higher performance and higher quality image capturing functions in the electronic devices.

The above information is presented as background information only to assist with an understanding the disclosure. No determination has been made, and no assertion is made, as to whether any of the above might be applicable as prior art with regard to the disclosure.

### SUMMARY

According to an embodiment, the electronic device may provide an experience of a camera with an interchangeable lens system of a digital camera (e.g., a digital single lens reflex (DSLR) camera) by applying multiple cameras (e.g., a main camera, a wide-angle camera, and a zoom camera). For example, the electronic device may provide a zoom camera (e.g., a camera with different magnification from a camera with approximately 1× magnification) with fixed zoom magnification (e.g., approximately 3× magnification or approximately 10× magnification) to clearly capture distant landscapes or subjects. For example, the electronic device may apply multiple zoom cameras to provide a high-magnification zoom function, thereby improving the zoom performance of a camera and providing high-quality images.

The electronic device may include a time of flight (TOF) camera. For example, the electronic device may support capturing a two-dimensional image using a general camera, and may support capturing a three-dimensional image using the TOF camera. The TOF camera may include a camera that provides a depth image by using a TOF scheme that calculates a depth by measuring the time it takes for light to be emitted and reflected back. According to an embodiment, the electronic device may provide a function of calculating a depth between the electronic device and an object using the TOF camera and focusing a general camera based on the calculated depth. According to another embodiment, the electronic device may calculate a depth between several other objects included in a preview image using the TOF camera to provide depth information between the objects and/or length information of the objects, or may quickly configure or provide an augmented reality (AR) image such as adding a virtual image between the objects. Due to various advantages of the TOF camera, the use and utilization of the TOF camera have been increasing recently.

However, when the TOF camera is used in the electronic device, the time of flight (TOF) sensor is always operating, which may increase the current consumption of the electronic device. Therefore, the usage time of the electronic device may also be reduced depending on the use of the TOF camera.

Aspects of the disclosure are to address at least the above-mentioned problems and/or disadvantages and to provide at least the advantages described below. Accordingly, an aspect of the disclosure is to provide a method for reducing current consumption by adaptively controlling on/off of a TOF function during camera operation in an electronic device and an electronic device supporting the same.

Another aspect of the disclosure is to provide a method for reducing current consumed by an operation of a time of flight (TOF) sensor and an electronic device supporting the same.

An embodiment of the disclosure is directed to providing a method capable of reducing current consumption through phase locked loop (PLL) control of a TOF sensor based on whether a data error has occurred due to a serial peripheral interface (SPI) communication speed of the TOF sensor and an electronic device supporting the same.

Another aspect of the disclosure is to provide a method capable of reducing current consumption by differently processing PLL control of a TOF sensor depending on presence or absence of a data error during the operation and communication of a TOF and an electronic device supporting the same.

Additional aspects will be set forth in part in the description which follows and, in part, will be apparent from the description, or may be learned by practice of the presented embodiments.

In accordance with an aspect of the disclosure, an electronic device is provided. The electronic device includes a camera module including a plurality of cameras, a time of flight (TOF) sensor, memory, comprising one or more storage media, storing instructions, and one or more processors communicatively coupled to the camera module, the TOF sensor, and the memory, wherein the instructions, when executed by the one or more processors individually or collectively, cause the electronic device to detect operations of the camera module and the TOF sensor, identify at least one designated condition associated with setting an operation of the TOF sensor, determine whether to change the setting of the TOF sensor based on the designated condition, perform communication with the TOF sensor based on a first designated communication speed corresponding to a default setting when it is determined that the setting is not changed, change the setting of the TOF sensor from the default setting to a designated setting when it is determined that the setting is changed, perform communication with the TOF sensor based on a second designated communication speed adjusted in response to the change in the setting.

In accordance with another aspect of the disclosure, a method for operating an electronic device is provided. The method includes detecting operations of a camera module and a time of flight (TOF) sensor, identifying at least one designated condition associated with setting an operation of the TOF sensor, determining whether to change the setting of the TOF sensor based on the designated condition, performing communication with the TOF sensor based on a first designated communication speed corresponding to a default setting when it is determined that the setting is not changed, changing the setting of the TOF sensor from the default setting to a designated setting when it is determined that the setting is changed, performing communication with the TOF sensor based on a second designated communication speed adjusted in response to the change in the setting.

To solve the above-described problems, according to various embodiments of the disclosure, there may be provided a computer-readable medium on which a program for causing a processor to execute the above method is recorded.

In accordance with another aspect of the disclosure, one or more non-transitory computer-readable storage media storing one or more computer programs including computer-executable instructions that, when executed by one or more processors of an electronic device individually or collectively, cause the electronic device to perform operations are provided. The operations include detecting operations of a camera module and a time of flight (TOF) sensor, identifying at least one designated condition associated with setting an operation of the TOF sensor, determining whether to change the setting of the TOF sensor based on the designated condition, performing communication with the TOF sensor based on a first designated communication speed corresponding to a default setting when it is determined that the setting is not changed, changing the setting of the TOF sensor from the default setting to a designated setting when it is determined that the setting is changed, and performing communication with the TOF sensor based on a second designated communication speed adjusted in response to the change in the setting.

Additional scope of applicability of the disclosure will be made clear from the following detailed description. However, various changes and modification within the spirit and scope of the disclosure can be clearly understood by those skilled in the art, so the detailed description and specific embodiments such as preferred embodiments of the disclosure should be understood only as examples.

According to an electronic device, an operation method thereof, and a recording medium according to an embodiment of the disclosure, by adaptively controlling the on/off of the TOF function during the camera operation in the electronic device, it is possible to reduce the current consumption. According to an embodiment, by reducing the current consumption due to the operation of the TOF sensor during the camera operation, it is possible to support preventing the data errors in communication between the camera and the TOF sensor.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment according to an embodiment of the disclosure;

FIG. 2 is a diagram schematically illustrating a configuration of an electronic device according to an embodiment of the disclosure;

FIG. 3 is a flowchart illustrating a method for operating an electronic device according to an embodiment of the disclosure;

FIG. 4 is a flowchart illustrating the method for operating an electronic device according to an embodiment of the disclosure;

FIG. 5 is a flowchart illustrating the method for operating an electronic device according to an embodiment of the disclosure;

FIG. 6 is a diagram illustrating an example of variably operating a data zone of a TOF sensor according to an embodiment of the disclosure;

FIG. 7 is a diagram illustrating an example of variably operating a data zone of a TOF sensor according to an embodiment of the disclosure;

FIG. 8 is a diagram illustrating an example of operating a low power mode that reduces a current by reducing a surface-emitting laser (VCSEL) emission time of a TOF sensor according to an embodiment of the disclosure;

FIG. 9 is a diagram illustrating an example of a current reduction difference according to a turn-off of the PLL for each integration time of a TOF sensor according to an embodiment of the disclosure; and

FIG. 10 is a diagram illustrating an example of a current reduction difference according to the turn-off of the PLL for each integration time of a TOF sensor according to an embodiment of the disclosure.

The same reference numerals are used to represent the same elements throughout the drawings.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

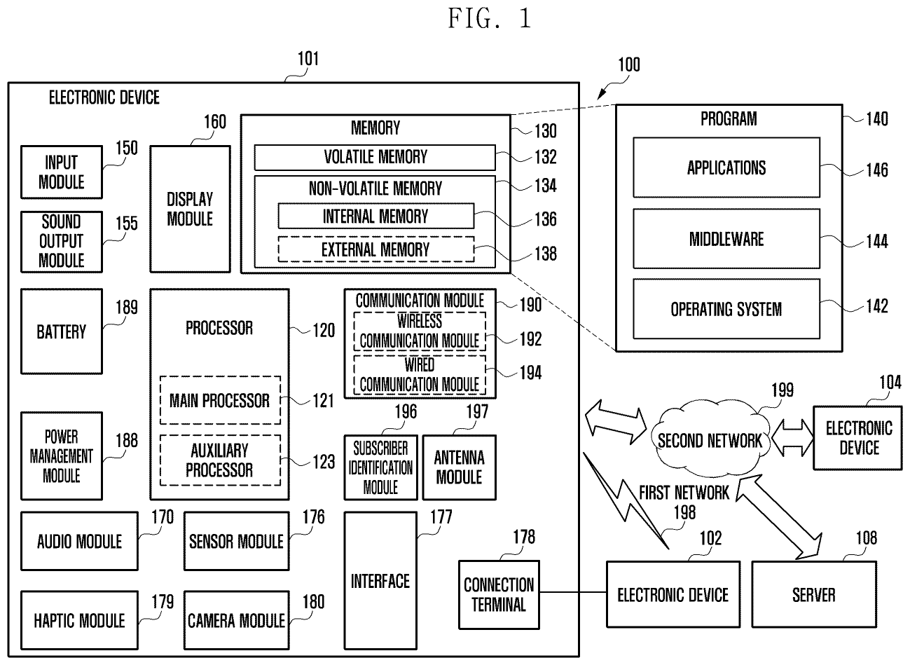

FIG. 1 is a block diagram illustrating an electronic device 101 in a network environment 100 according to an embodiment of the disclosure.

Referring to FIG. 1, the electronic device 101 in the network environment 100 may communicate with an electronic device 102 via a first network 198 (e.g., a short-range wireless communication network), or at least one of an electronic device 104 or a server 108 via a second network 199 (e.g., a long-range wireless communication network). In an embodiment, the electronic device 101 may communicate with the electronic device 104 via the server 108. According to an embodiment, the electronic device 101 may include a processor 120, memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one of the components (e.g., the connecting terminal 178) may be omitted from the electronic device 101, or one or more other components may be added in the electronic device 101. In some embodiments, some of the components (e.g., the sensor module 176, the camera module 180, or the antenna module 197) may be implemented as a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to an embodiment, as at least part of the data processing or computation, the processor 120 may store a command or data received from another component (e.g., the sensor module 176 or the communication module 190) in volatile memory 132, process the command or the data stored in the volatile memory 132, and store resulting data in non-volatile memory 134. According to another embodiment, the processor 120 may include a main processor 121 (e.g., a central processing unit (CPU) or an application processor (AP)), or an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. For example, when the electronic device 101 includes the main processor 121 and the auxiliary processor 123, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). The auxiliary processor 123 (e.g., an image signal processor or a communication processor) may be implemented as part of another component (e.g., the camera module 180 or the communication module 190) functionally related to the auxiliary processor 123. According to another embodiment, the auxiliary processor 123 (e.g., the neural processing unit) may include a hardware structure specified for artificial intelligence model processing. An artificial intelligence model may be generated by machine learning. Such learning may be performed, e.g., by the electronic device 101 where the artificial intelligence is performed or via a separate server (e.g., the server 108). Learning algorithms may include, but are not limited to, e.g., supervised learning, unsupervised learning, semi-supervised learning, or reinforcement learning. The artificial intelligence model may, for example, include a plurality of artificial neural network layers. The artificial neural network may be a deep neural network (DNN), a convolutional neural network (CNN), a recurrent neural network (RNN), a restricted boltzmann machine (RBM), a deep belief network (DBN), a bidirectional recurrent deep neural network (BRDNN), deep Q-network or a combination of two or more thereof but is not limited thereto. The artificial intelligence model may, additionally or alternatively, include a software structure other than the hardware structure.

The memory 130 may store various data used by at least one component (e.g., the processor 120 or the sensor module 176) of the electronic device 101. The various data may include, for example, software (e.g., the program 140) and input data or output data for a command related thererto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by another component (e.g., the processor 120) of the electronic device 101, from the outside (e.g., a user) of the electronic device 101. In another embodiment, the input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record. The receiver may be used for receiving incoming calls. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to another embodiment, the display module 160 may include a touch sensor adapted to detect a touch, or a pressure sensor adapted to measure the intensity of force incurred by the touch.

The audio module 170 may convert a sound into an electrical signal and vice versa. According to another embodiment, the audio module 170 may obtain the sound via the input module 150, or output the sound via the sound output module 155 or a headphone of an external electronic device (e.g., an electronic device 102) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. The sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to another embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. The haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. In an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to another embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). A corresponding one of these communication modules may communicate with the external electronic device via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, a fifth generation (5G) network, a next-generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify and authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network, after a fourth generation (4G) network, and next-generation communication technology, e.g., new radio (NR) access technology. The NR access technology may support enhanced mobile broadband (eMBB), massive machine type communications (mMTC), or ultra-reliable and low-latency communications (URLLC). The wireless communication module 192 may support a high-frequency band (e.g., the millimeter wave (mmWave) band) to achieve, e.g., a high data transmission rate. The wireless communication module 192 may support various technologies for securing performance on a high-frequency band, such as, e.g., beamforming, massive multiple-input and multiple-output (massive MIMO), full dimensional MIMO (FD-MIMO), array antenna, analog beam-forming, or large scale antenna. The wireless communication module 192 may support various requirements specified in the electronic device 101, an external electronic device (e.g., the electronic device 104), or a network system (e.g., the second network 199). The wireless communication module 192 may support a peak data rate (e.g., 20 Gbps or more) for implementing eMBB, loss coverage (e.g., 164 dB or less) for implementing mMTC, or U-plane latency (e.g., 0.5 ms or less for each of downlink (DL) and uplink (UL), or a round trip of 1 ms or less) for implementing URLLC.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., a printed circuit board (PCB)). According to an embodiment, the antenna module 197 may include a plurality of antennas (e.g., array antennas). In such a case, at least one antenna appropriate for a communication scheme used in the communication network, such as the first network 198 or the second network 199, may be selected, for example, by the communication module 190 (e.g., the wireless communication module 192) from the plurality of antennas. The signal or the power may then be transmitted or received between the communication module 190 and the external electronic device via the selected at least one antenna. According to another embodiment, another component (e.g., a radio frequency integrated circuit (RFIC)) other than the radiating element may be additionally formed as part of the antenna module 197.

According to some embodiments, the antenna module 197 may form a mmWave antenna module. According to an embodiment, the mmWave antenna module may include a printed circuit board, a RFIC disposed on a first surface (e.g., the bottom surface) of the printed circuit board, or adjacent to the first surface and capable of supporting a designated high-frequency band (e.g., the mmWave band), and a plurality of antennas (e.g., array antennas) disposed on a second surface (e.g., the top or a side surface) of the printed circuit board, or adjacent to the second surface and capable of transmitting or receiving signals of the designated high-frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

In an embodiment, commands or data may be transmitted or received between the electronic device 101 and the external electronic device 104 via the server 108 coupled with the second network 199. Each of the electronic devices 102 or 104 may be a device of a same type as, or a different type, from the electronic device 101. According to an embodiment, all or some of operations to be executed at the electronic device 101 may be executed at one or more of the external electronic devices 102, 104, or 108. For example, if the electronic device 101 should perform a function or a service automatically, or in response to a request from a user or another device, the electronic device 101, instead of, or in addition to, executing the function or the service, may request the one or more external electronic devices to perform at least part of the function or the service. The one or more external electronic devices receiving the request may perform the at least part of the function or the service requested, or an additional function or an additional service related to the request, and transfer an outcome of the performing to the electronic device 101. The electronic device 101 may provide the outcome, with or without further processing of the outcome, as at least part of a reply to the request. To that end, a cloud computing, distributed computing, mobile edge computing (MEC), or client-server computing technology may be used, for example. The electronic device 101 may, for example, provide ultra low-latency services using, e.g., distributed computing or mobile edge computing. In another embodiment, the external electronic device 104 may include an internet-of-things (IoT) device. The server 108 may be an intelligent server using machine learning and/or a neural network. According to an embodiment, the external electronic device 104 or the server 108 may be included in the second network 199. The electronic device 101 may be applied to intelligent services (e.g., smart home, smart city, smart car, or healthcare) based on 5G communication technology or IoT-related technology.

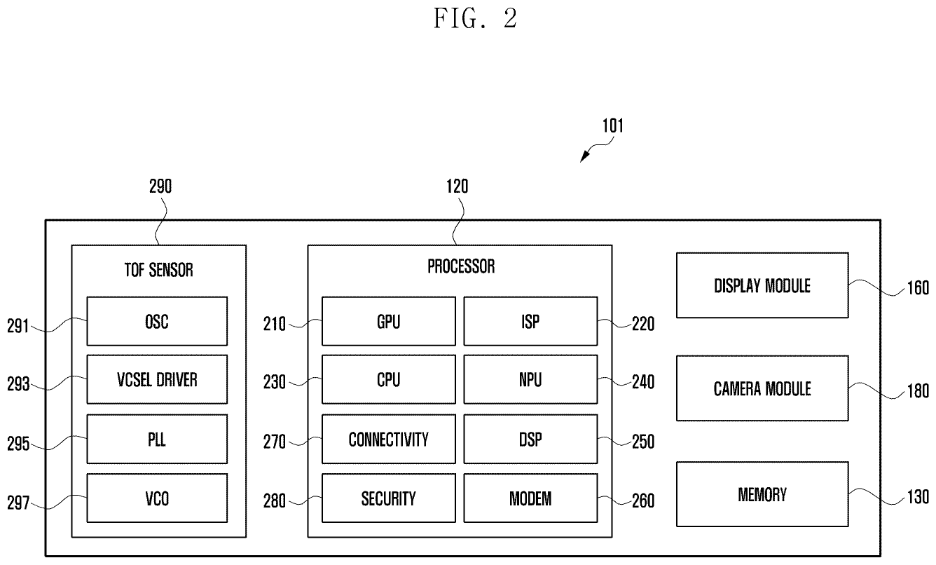

FIG. 2 is a diagram schematically illustrating a configuration of an electronic device according to an embodiment of the disclosure.

Referring to FIG. 2, an electronic device 101 according to an embodiment of the disclosure may include a display module 160, a camera module 180, memory 130, a time of flight (TOF) sensor 290, and/or a processor 120. According to an embodiment, the electronic device 101 may include all or at least a part of the components of the electronic device 101 as described in the description part referring to FIG. 1.

According to an embodiment, the display module 160 may include a component identical to or similar to the display module 160 of FIG. 1. According to an embodiment, the display module 160 may include a display, and may visually provide various pieces of information to an outside (e.g., a user) of the electronic device 101 through the display. According to an embodiment, the display module 160 may visually provide, under the control of the processor 120, an application (e.g., an application 146 of FIG. 1) to be executed and various pieces of information (e.g., content, images, videos, preview images) related to its use.

The display module 160 may include a touch sensor, a pressure sensor capable of measuring the intensity of a touch, and/or a touch panel (e.g., a digitizer) that detects a stylus pen of a magnetic field type. According to an embodiment, the display module 160 may detect a touch input and/or a hovering input (or a proximity input) by measuring a change in a signal (e.g., voltage, light amount, resistance, electromagnetic signal, and/or charge amount) for a specific position of the display module 160 based on the touch sensor, the pressure sensor, and/or the touch panel. According to an embodiment, the display module 160 may include a liquid crystal display (LCD), an organic light emitting diode (OLED), or an active matrix organic light emitting diode (AMOLED). The display module 160 may include a flexible display.

According to an embodiment, the camera module 180 may correspond to the camera module 180 of FIG. 1. According to another embodiment, the camera module 180 may, when activated, capture a subject and transmit a related result (e.g., a captured image) to the processor 120 and/or the display module 160. According to an embodiment, the camera module 180 may include a plurality of cameras (e.g., a main camera, a wide-angle camera, and a zoom camera). For example, the camera module 180 may apply the plurality of cameras to provide a camera experience of an interchangeable lens system of a digital camera (e.g., a digital single lens reflex (DSLR) camera). For example, the electronic device 101 may provide a zoom camera (e.g., a camera with different magnification from a camera with approximately 1× magnification) with fixed zoom magnification (e.g., approximately 3× magnification or approximately 10× magnification) to clearly capture distant landscapes or subjects. For example, the electronic device 101 may apply multiple zoom cameras to provide a high-magnification zoom function, thereby improving the zoom performance of a camera and providing high-quality images.

According to an embodiment, the camera module 180 may operate by linking with the TOF sensor 290 or include a TOF camera in which the TOF sensor 290 is integrally included (or combined). For example, the TOF may represent a method of calculating a depth by measuring the time of flight, that is, the time it takes for light (e.g., infrared) to be emitted and reflected back. In the TOF camera, a light source that emits light and a detector (e.g., a TOF sensor 290) that detects light may operate as a pair, and the TOF camera may represent a camera that captures an image (e.g., a three-dimensional image) that includes depth information using a TOF scheme.

The camera module 180 may capture an external subject (or object) and generate image data. For example, the camera module 180 may include an image sensor. According to an embodiment, the image sensor may include a multi pixel sensor (MPS). The camera module 180 may convert an optical signal of a subject into an electrical signal by the image sensor. To this end, the image sensor may include a pixel array in which a plurality of pixels are arranged two-dimensionally. For example, one of a plurality of reference colors may be assigned to each of the plurality of pixels. For example, the plurality of reference colors may include red, green, and blue (RGB), or red, green, blue, and white (RGBW).

According to another embodiment, the camera module 180 may generate image data using an image sensor. In an embodiment, the image data may be referred to variously like an image, a non-Bayer image, an image frame, and frame data. According to an embodiment, the image data may be provided as input data to the processor 120 (e.g., an image signal processor (ISP) 220 and/or a neural processing unit (NPU) 240) or stored in the memory 130. In an embodiment, the image data stored in the memory 130 may be provided to the processor 120.

According to an embodiment, the TOF sensor 290 may be a three-dimensional sensor, and represent a sensor that calculates a depth by measuring the time it takes for light in an infrared wavelength to be emitted toward an object and reflected back, and recognizes three-dimensionality and spatial information of an object and/or movement. In an embodiment, the TOF sensor 290 may represent a sensor that measures (or calculates) the depth by detecting the time of flight, that is, the light emitted to the front and reflected back. In an example, the TOF sensor 290 may calculate the depth by measuring the time for a designated signal (e.g., infrared, ultrasound, or laser) to be emitted and reflected back. According to an embodiment, the TOF sensor 290 may provide depth information to an image captured by the camera module 180 when the camera module 180 is in operation.

The TOF sensor 290 may emit a light source of a specific frequency to detect the depth. According to an embodiment, the TOF sensor 290 may include a PLL 295 to accurately match a VCSEL emission period and a clock (CLK) between the SPI communications. According to an embodiment, the TOF sensor 290 may adjust the SPI communication speed by controlling a serial CLK (SCLK) speed from a master (e.g., the processor 120). In an embodiment, the SCLK may represent a synchronous clock (or clock signal) output from the master (e.g., the processor 120). For example, the communication (e.g., data exchange) between the master (e.g., the processor 120) and the slave (e.g., the TOF sensor 290) may proceed based on the SCLK.

In an embodiment, the TOF sensor 290 may be configured in the form of a system-on-chip (SoC), and may include a technology-intensive semiconductor chip that integrates multiple semiconductor technologies into one and implements system blocks into one chip. According to an embodiment, as illustrated in FIG. 2, the system blocks of the TOF sensor 290 may include blocks corresponding to an oscillator (OSC) 291, a vertical-cavity surface-emitting laser (VCSEL) driver 293, and a phase locked loop (PLL) 295.

According to an embodiment, the OSC 291 may serve to generate a sine wave signal source (e.g., a frequency source) of a frequency required by the TOF sensor 290.

According to another embodiment, the VCSEL driver 293 may serve to detect an object by emitting (or radiating) a light source (e.g., a VCSEL) that emits light. In an embodiment, the VCSEL may be the light source that emits light, and infrared, ultrasound, and/or laser may be used.

According to an embodiment, the PLL 295 may serve to improve the accuracy of communication through frequency modulation and/or phase locking. According to an embodiment, the PLL 295 may represent a feedback circuit designed to be able to synchronize a phase of a clock with an external timing signal. According to an embodiment, the PLL 295 may include a voltage controlled oscillator (VCO) 297 therein. According to an embodiment, the PLL 295 may operate by comparing the phase of the external timing signal with a phase of a clock signal generated by the VCO 297. The PLL 295 may control the VCSEL emission in the TOF sensor 290 to operate at a designated synchronous timing, and serve to prevent a communication error from occurring in serial communication (e.g., serial peripheral interface (SPI) communication) between the slave (e.g., the TOF sensor 290) and the master (e.g., the processor 120). In the case of the TOF sensor 290, a large difference in current consumption may occur depending on whether the PLL 295 operates internally.

According to an embodiment, the memory 130 may correspond to the memory 130 of FIG. 1. According to an embodiment, the memory 130 may store various data used by the electronic device 101. The data may include, for example, input data or output data for an application (e.g., the program 140 of FIG. 1) and a command related to the application. According to an embodiment, the data may include image data acquired through the camera module 180. According to an embodiment, the data may include depth information (or depth data) acquired through the TOF sensor 290. The data may include information about various settings (e.g., various settings for supporting an operation (e.g., low power mode) according to the reduction in current consumption of the TOF sensor 290 during operation based on the linkage between the TOF sensor 290 and the camera module 180) related to the operation of the TOF sensor 290. According to an embodiment, the information about various settings may include, for example, information about an operation period of the TOF sensor 290, conditions for controlling the PLL 295, and/or criteria (e.g., criteria for determining whether a data error has occurred) for determining the control of the PLL 295. According to another embodiment, the data may include various training data and parameters acquired based on user's learning through interaction with the user. According to an embodiment, the data may include various schema (or an algorithm, a model, a network, or a function) for supporting the low power mode (e.g., operating mode for supporting a reduction in current consumption) of the TOF sensor 290 during the operation based on the linkage between the TOF sensor 290 and the camera module 180.

For example, the schema for supporting the low power mode of the TOF sensor 290 may include a neural network. According to yet another embodiment, the neural network may include a neural network model based on at least one of an artificial neural network (ANN), a convolution neural network (CNN), a region with convolution neural network (R-CNN), a region proposal network (RPN), a recurrent neural network (RNN), a stacking-based deep neural network (S-DNN), a state-space dynamic neural network (S-SDNN), a deconvolution network, a deep belief network (DBN), a restricted boltzman machine (RBM), a long short-term memory (LSTM) network, a classification network, a plain residual network, a dense network, a hierarchical pyramid network, and/or a fully convolutional network. According to an embodiment, the type of the neural network model is not limited to the examples described above.

According to an embodiment, the memory 130 may store instructions that cause the processor 120 to operate when executed. For example, the application may be stored as software (e.g., the program 140 of FIG. 1) on the memory 130 and may be executable by the processor 120. According to an embodiment, the application may be various applications that may provide various functions or services (e.g., a three-dimensional image capturing function including the depth information) in the electronic device 101.

The processor 120 may perform an application layer processing function requested by the user of the electronic device 101. According to an embodiment, the processor 120 may provide control and commands of functions for various blocks of the electronic device 101. According to an embodiment, the processor 120 may perform calculations or data processing related to control and/or communication of each component of the electronic device 101. For example, the processor 120 may include at least some of the components and/or functions of the processor 120 of FIG. 1. According to another embodiment, the processor 120 may be operatively connected to components of the electronic device 101. According to an embodiment, the processor 120 may load commands or data received from other components of the electronic device 101 into the memory 130, process commands or data stored in the memory 130, and store result data.

According to an embodiment, the processor 120 may be an application processor (AP). According to an embodiment, the processor 120 may be a system semiconductor that is in charge of the calculations and multimedia driving functions of the electronic device 101. The processor 120 may be configured in the form of a system-on-chip (SoC), and may include a technology-intensive semiconductor chip that integrates multiple semiconductor technologies into one and implements system blocks into one chip. According to an embodiment, as illustrated in FIG. 2, the system blocks of the processor 120 may include a graphics processing unit (GPU) 210, an image signal processor (ISP) 220, a central processing unit (CPU) 230, a neural processing unit (NPU) 240, a digital signal processor 250, a modem 260, a connectivity 270, and/or a security 280 block.

According to an embodiment, the GPU 210 may be in charge of graphics processing. According to yet another embodiment, the GPU 210 may receive commands from the CPU 230 and perform graphics processing to express shapes, positions, colors, shades, movements, and/or textures of things (or objects) on a display.

According to an embodiment, the ISP 220 may be in charge of image processing and correction of images and videos. According to an embodiment, the ISP 220 may correct unprocessed data (e.g., raw data) transmitted from the image sensor of the camera module 180 to generate an image in a form more preferred by the user. The ISP 220 may perform post-processing such as adjusting partial brightness of the image and emphasizing detailed parts. For example, the ISP 220 may independently perform a quality tuning and correction process of the image acquired through the camera module 180 to generate results preferred by the user.

In an embodiment, the ISP 220 may support a scene segmentation (e.g., image segmentation) technology that recognizes and/or classifies parts of a scene being captured by linking with the NPU 240. For example, the ISP 220 may include a function to process objects such as sky, bushes, and/or skin by applying different parameters to the objects. The ISP 220 may detect and display a human face when capturing an image through an artificial intelligence function, or may adjust the brightness, focus, and/or color of the image using the coordinates and information of the face.

According to an embodiment, the CPU 230 may perform a role corresponding to the processor 120. According to an embodiment, the CPU 230 may decipher a user's command, perform a role of arithmetic and logical operations, and/or data processing. For example, the CPU 230 may perform functions such as memory, interpretation, calculation, and control. According to an embodiment, the CPU 230 may control an overall function of the electronic device 101. For example, the CPU 230 may execute all software (e.g., applications) of the electronic device 101 on an operating system (OS) and control a hardware device.

According to an embodiment, the CPU 230 may include one processor core (single core) or multiple processor cores (multi-core). The CPU 230 may execute an application and control the overall operation of the processor 120 to perform neural network-based tasks required according to the execution of the application.

According to an embodiment, the NPU 240 may be in charge of processing optimized for a deep-learning algorithm of artificial intelligence. According to another embodiment, the NPU 240 is a processor optimized for a deep-learning algorithm operation (e.g., an artificial intelligence operation) and may process big data quickly and efficiently like a human neural network. For example, the NPU 240 may be mainly used for the artificial intelligence operation. According to an embodiment, the NPU 240 may be in charge of processing that recognizes objects, environments, and/or people in the background when capturing an image through the camera module 180 to automatically adjust a focus, automatically switches a capturing mode of the camera module 180 to food mode when capturing a food picture, and/or erases only unnecessary subjects from the captured results.

According to an embodiment, the electronic device 101 may support integrated machine learning processing by interacting with all processors such as the GPU 210, the ISP 220, the CPU 230, and the NPU 240.

According to another embodiment, the DSP 250 may represent an integrated circuit that helps to quickly process a digital signal. According to an embodiment, the DSP 250 may perform a function of converting an analog signal into a digital signal and performing high-speed processing.

In an embodiment, the modem 260 may perform a role that allows the electronic device 101 to use various communication functions. For example, the modem 260 may support communication such as telephone and data transmission and reception while exchanging signals with a base station. According to an embodiment, the modem 260 may include an integrated modem (e.g., a cellular modem, an LTE modem, a 5G modem, a 5G-Advanced modem, and a 6G modem) that supports communication technologies such as LTE and 2G to 5G. According to an embodiment, the modem 260 may include an artificial intelligence modem that applies an artificial intelligence algorithm.

According to an embodiment, the connectivity 270 may support wireless data transmission based on IEEE 802.11. According to an embodiment, the connectivity 270 may support communication services based on IEEE 802.11 (e.g., Wi-Fi) and/or 802.15 (e.g., Bluetooth, ZigBee, and UWB). For example, the connectivity 270 may support communication services for an unspecified number of people in a localized area such as indoors using an unlicensed band.

The security 280 may provide an independent security execution environment between data or services stored in the electronic device 101. According to an embodiment, the security 280 may play a role in preventing hacking from the outside through software and hardware security during user authentication when providing services such as biometric recognition, mobile ID, and/or payment of the electronic device 101. For example, security 280 may provide an independent security execution environment in device security for enhancing the security of the electronic device 101 itself and in security services based on user information such as mobile ID, payment, and car keys in the electronic device 101.

According to an embodiment of the disclosure, the processor 120 may execute an application and execute (or turn-on) the camera module 180 and the TOF sensor 290 according to the execution of the application. The processor 120 may control the overall operation of capturing an image (e.g., a 3D image) that includes depth information through image processing of the depth information acquired from the TOF sensor 290 and the image acquired from the camera module 180. According to an embodiment, the processor 120 may control overall operations related to supporting the low power mode (e.g., the operating mode for supporting the reduction in current consumption) of the TOF sensor 290 during operation (e.g., a 3D image capturing function) based on the linkage between the TOF sensor 290 and the camera module 180.

According to an embodiment of the disclosure, the processor 120 may include processing circuitry and/or executable program elements. According to an embodiment, the processor 120 may control (or process) operations related to operating the low power mode (e.g., the operating mode for supporting the reduction in current consumption) of the TOF sensor 290 based on the processing circuitry and/or executable program elements.

According to an embodiment, the processor 120 may perform an operation of detecting operations of the camera module 180 and the time of flight (TOF) sensor 290. According to an embodiment, the processor 120 may perform an operation of identifying at least one designated condition associated with setting the operation of the TOF sensor 290. According to an embodiment, the processor 120 may perform an operation of determining whether to change the setting of the TOF sensor 290 based on the designated condition. According to another embodiment, when the processor 120 determines that the setting is not changed, the processor 120 may perform an operation of performing the communication (e.g., serial communication) with the TOF sensor 290 based on a first designated communication speed corresponding to the default setting. According to an embodiment, when the processor 120 determines that the setting is changed, the processor 120 may perform the operation of changing the setting of the TOF sensor 290 from the default setting to the designated setting. According to yet another embodiment, the processor 120 may perform an operation of performing the communication with the TOF sensor 290 based on a second designated communication speed adjusted in response to the change in the setting.

According to an embodiment, the detailed operation of the processor 120 of the electronic device 101 will be described with reference to the drawings described below.

According to an embodiment, the operations performed by the processor 120 may be implemented as a recording medium (or a computer program product). For example, the recording medium may include a non-transitory computer-readable medium that records a program for executing various operations performed by the processor 120.

Various embodiments described in the disclosure may be implemented in a computer or a computer-readable medium using software, hardware, or a combination of software and hardware. According to a hardware implementation, operations described in an embodiment may be implemented using at least one of application specific integrated circuits (ASICs), digital signal processors (DSPs), digital signal processing devices (DSPDs), programmable logic devices (PLDs), field programmable gate arrays (FPGAs), processors, controllers, micro-controllers, microprocessors, and/or electric units for executing other functions.

The recording medium (or computer program product) may include a computer-readable medium on which a program for executing the following operations is recorded: detecting the operations of the camera module 180 and the time of flight (TOF) sensor 290; identifying at least one designated condition associated with setting the operation of the TOF sensor 290; determining whether to change the setting of the TOF sensor 290 based on the designated condition; performing the communication with the TOF sensor 290 based on the first designated communication speed corresponding to the default setting when determining that the setting is not changed; performing the operation of changing the setting of the TOF sensor 290 from the default setting to the designated setting when determining that the setting is changed; and performing the communication with the TOF sensor 290 based on the second designated communication speed adjusted in response to the change in the setting.

The electronic device 101 according to an embodiment of the disclosure may include the camera module including the plurality of cameras (e.g., the camera module 180 of FIG. 1 or 2), the time of flight (TOF) sensor (e.g., the TOF sensor 290 of FIG. 2), the memory (e.g., the memory 130 of FIG. 1) storing instructions, and the processor (e.g., the processor 120 of FIG. 1 or 2) operatively connected to the camera module 180, the TOF sensor 290, and the memory 130.

According to an embodiment, when executed by the processor 120, the instructions may cause the electronic device 101 to detect the operations of the camera module 180 and the TOF sensor 290. According to an embodiment, when executed by the processor 120, the instructions may cause the electronic device 101 to identify at least one designated condition associated with setting the operation of the TOF sensor 290. According to another embodiment, when executed by the processor 120, the instructions may cause the electronic device 101 to determine whether to change the setting of the TOF sensor 290 based on the designated condition. When executed by the processor 120, the instructions may cause the electronic device 101 to perform the communication with the TOF sensor 290 based on the first designated communication speed corresponding to the default setting when it is determined that the setting is not changed. According to an embodiment, when executed by the processor 120, the instructions may cause the electronic device 101 to change the setting of the TOF sensor 290 from the default setting to the designated setting when it is determined that the setting is changed. When executed by the processor 120, the instructions may cause the electronic device 101 to perform the communication with the TOF sensor 290 based on the second designated communication speed adjusted in response to the change in the setting.

According to an embodiment, when executed by the processor 120, the instructions may cause the electronic device 101 to execute the TOF sensor 290 when the camera module 180 is executed or in response to the entry of the capturing mode designated for the camera module 180.

According to an embodiment, the TOF sensor 290 may include a VCSEL driver (e.g., the VCSEL driver 293 of FIG. 2) that detects an object by emitting the vertical-cavity surface-emitting laser (VCSEL) that emits light, and the phase locked loop (PLL) (e.g., the PLL 295 of FIG. 2) that controls the VCSEL emission in the TOF sensor 290 to operate at the designated synchronous timing and prevents the communication error in the serial communication between the TOF sensor 290 and the processor 120.

When executed by the processor 120, the instructions may cause the electronic device 101 to control the TOF sensor 290 to operate at the first designated communication speed and a first state of the PLL 295 based on the default setting of the TOF sensor 290.

According to another embodiment, when executed by the processor 120, the instructions may cause the electronic device 101 to determine at least one designated condition related to the control of the PLL 295 of the TOF sensor 290. According to an embodiment, the at least one designated condition may include the condition in which the data error has occurred in the serial communication according to the occupancy rate of the processor 120, the amount of data according to the change in the data zone of the TOF sensor 290, the temperature of the processor 120, and/or the capturing mode of the camera module 180.

According to an embodiment, when executed by the processor 120, the instructions may cause the electronic device 101 to determine the change in the setting of the TOF sensor 290 when the operating state of the electronic device 101 corresponding to the at least one designated condition is identified.

When executed by the processor 120, the instructions may cause the electronic device 101 to control the TOF sensor 290 to operate at the second designated communication speed faster than the first designated speed and a second state of the PLL 295 when determining the change in the setting of the TOF sensor 290.

According to an embodiment, when executed by the processor 120, the instructions may cause the electronic device 101 to control the TOF sensor 290 to operate by changing the first state (PLL=OFF) of the PLL 295 to the second state (PLL=ON) in order to prevent the data corruption that may occur due to the communication based on the second designated communication speed.

When executed by the processor 120, the instructions may cause the electronic device 101 to determine whether to control the PLL 295 based on whether the data error has occurred due to the serial communication.

According to an embodiment, when executed by the processor 120, the instructions may cause the electronic device 101 to acquire the designated information from the TOF sensor 290. When executed by the processor 120, the instructions may cause the electronic device 101 to determine whether the data error has occurred based on the designated information. According to an embodiment, when executed by the processor 120, the instructions may cause the electronic device 101 to change the PLL 295 of the TOF sensor 290 to the ON state based on determining that the data error has occurred.

In an embodiment, when executed by the processor 120, the instructions may cause the electronic device 101 to acquire the designated information from the TOF sensor 290 to determine the on/off control of the PLL 295 when detecting the operation of the TOF sensor 290.

According to an embodiment, the designated information may represent unique information related to the TOF sensor 290 and may include the device identifier (device ID) and/or the firmware identifier (firmware ID).

The method for operating the electronic device 101 according to various embodiments will be described in detail. The operations performed in the electronic device 101 according to various embodiments may be executed by the processor 120 including various processing circuitry and/or executable program elements of the electronic device 101. According to an embodiment, the operations performed in the electronic device 101 may be stored in the memory 130 and executed by instructions that cause the processor 120 to operate when executed.

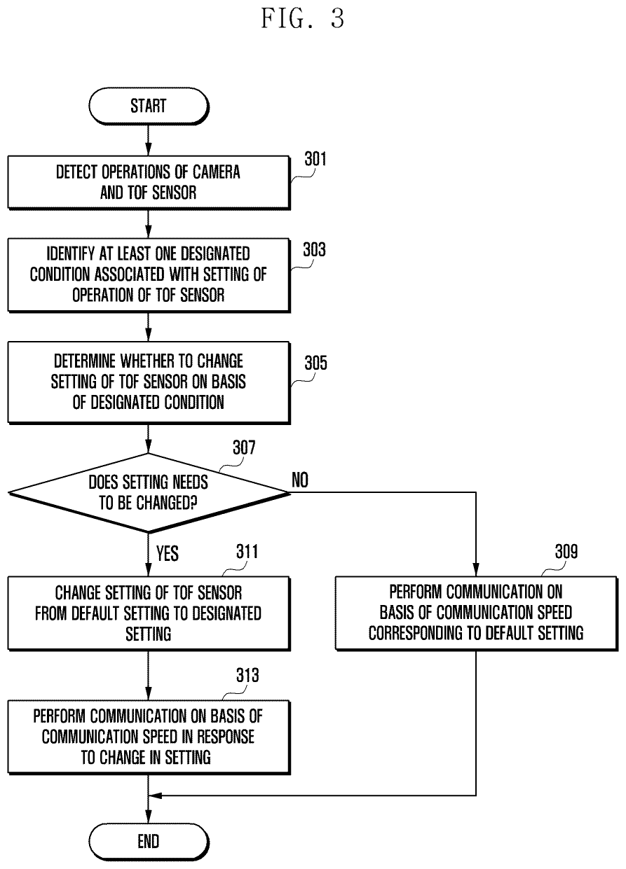

FIG. 3 is a flowchart illustrating a method for operating an electronic device according to an embodiment of the disclosure.

According to an embodiment, FIG. 3 may represent an example of supporting the method for operating the low power mode (e.g., the operating mode for supporting the reduction in current consumption) of the TOF sensor 290 when capturing the image including the depth information in the electronic device 101 according to an embodiment (e.g., the operation (e.g., the three dimensional (3D) image capturing function) based on the linkage between the TOF sensor 290 of FIG. 2 and the camera module 180 of FIG. 1 or 2).

In the electronic device (e.g., the electronic device 101 of FIG. 1 or 2) according to an embodiment of the disclosure, the method for supporting the operation of the low power mode may be performed according to, for example, a flowchart illustrated in FIG. 3. The flowchart illustrated in FIG. 3 is merely a flowchart according to an embodiment of the operation of the electronic device 101, and the order of at least some operations may be changed or performed in parallel, performed as an independent operation, or at least some other operations may be performed complementarily to at least some operations. According to an embodiment of the disclosure, operations 301 to 315 may be performed in at least one processor (e.g., the processor 120 of FIG. 1 or 2) of the electronic device 101.

Referring to FIG. 3, the operation method performed by the electronic device 101 according to an embodiment may include an operation 301 of detecting the operations of the camera (e.g., the camera module 180 of FIG. 1 or 2) and the TOF sensor (e.g., the TOF sensor 290 of FIG. 2), an operation 303 of identifying at least one designated condition associated with setting the operation of the TOF sensor, operations 305 and 307 of determining whether to change the setting of the TOF sensor based on the designated condition, an operation 309 of performing the communication based on the communication speed corresponding to the default setting when it is determined that the change in the setting is not required, an operation 311 of changing the setting of the TOF sensor from the default setting to the designated setting when it is determined that the change in the setting is required, and an operation 313 of performing the communication based on the communication speed corresponding to the setting in the change.

Referring to FIG. 3, in operation 301, the processor 120 of the electronic device 101 may perform an operation of detecting the operation (e.g., execution) of the camera (e.g., the camera module 180 of FIG. 1 or 2) and the TOF sensor (e.g., the TOF sensor 290 of FIG. 2). According to an embodiment, the processor 120 may execute the application (e.g., the camera application) based on the user input. The processor 120 may execute (or activate or turn-on) the camera based on the execution of the application. According to an embodiment, the processor 120 may control the display module (e.g., the display module 160 of FIG. 1 or 2) to display the image (e.g., the preview image) acquired through the camera.

According to an embodiment, the processor 120 may execute (or activate or turn-on) the TOF sensor in response to the execution of the camera. According to an embodiment, the processor 120 may execute the TOF sensor in response to the entry of the designated capturing mode (e.g., the image capturing mode including the depth information) among the capturing modes (or scenarios) performed using the camera. In an embodiment, the processor 120 may execute the TOF sensor based on the default setting of the TOF sensor when executing the camera and the TOF sensor. For example, the processor 120 may control the TOF sensor to operate at the first designated communication speed (e.g., SPI speed=approximately 3 MHZ) and the first state of the PLL (e.g., PLL=OFF) according to the default setting for the TOF sensor.

In operation 303, the processor 120 may perform an operation of identifying at least one designated condition associated with setting the operation of the TOF sensor. According to another embodiment, at least one designated condition related to the PLL control (e.g., the operation state change) of the TOF sensor may be determined based on detecting the operations of the camera and the TOF sensor. In an embodiment, at least one designated condition may include various conditions that can cause errors in data (e.g., parity bit or dummy data) in the serial communication (e.g., SPI communication) depending on the occupancy rate of the processor 120 (e.g., AP), the amount of data due to the change in the data zone (e.g., TOF data zone) of the TOF sensor, the temperature of the processor 120, and/or the capturing mode of the camera (e.g., the camera module 180 of FIG. 1 or 2). According to an embodiment, the PLL control for each designated condition is described with reference to the drawings described below.

In operations 305 and 307, the processor 120 may perform an operation of determining whether to change the setting of the TOF sensor based on the designated condition. According to another embodiment, the processor 120 may determine that the change in the setting of the TOF sensor is required (e.g., setting change determination) when the operation state of the electronic device 101 corresponding to at least one designated condition is identified. According to an embodiment, the processor 120 may determine that the change in the setting of the TOF sensor is not required (e.g., setting maintenance determination) when the operation state of the electronic device 101 corresponding to at least one designated condition is not identified.

In operation 307, when the processor 120 determines to maintain the setting (or determines that the change in the setting for the TOF sensor is not required) (e.g., ‘No’ in operation 307), in operation 309, the processor 120 may perform an operation of performing the communication based on the communication speed corresponding to the default setting of the TOF sensor. According to an embodiment, the processor 120 may perform an operation of performing the communication with the TOF sensor based on the first designated communication speed (e.g., SPI speed=approximately 3 MHz) in the first state (e.g., PLL=OFF) without controlling the operation of the PLL of the TOF sensor in response to the current operation setting (e.g., the default setting) of the TOF sensor. For example, the processor 120 may control the TOF sensor to operate at the first designated communication speed (e.g., SPI speed=approximately 3 MHZ) and the first state of the PLL (e.g., PLL=OFF) according to the default setting for the TOF sensor.

In operation 307, when the processor 120 determines to change the setting (or determines that the change in the setting for the TOF sensor is required) (e.g., ‘Yes’ in operation 307), in operation 311, the processor 120 may perform an operation of changing the setting of the TOF sensor from the default setting to the designated setting. The processor 120 may change the default setting (e.g., SPI speed=approximately 3 MHz and PLL=OFF) of the TOF sensor to the designated setting (e.g., SPI speed=approximately 19 MHz and PLL=ON). For example, the processor 120 may control the TOF sensor to operate by determining the change in the SPI communication speed from the first designated communication speed (e.g., SPI speed=approximately 3 MHz) to the second designated communication speed (e.g., SPI speed=approximately 19 MHz) faster than the first designated communication speed in order to reduce the occupancy time of the TOF sensor, and changing the first state of the PLL (e.g., PLL=OFF) to the second state (e.g., PLL=ON) in order to prevent the data corruption that may occur due to the communication based on the second designated communication speed. For example, the processor 120 may adjust the communication speed of the TOF sensor to the second designated communication speed based on the switching of the PLL to the second state.

In operation 313, the processor 120 may perform an operation of performing the communication based on the communication speed corresponding to the setting in the change of the TOF sensor. The processor 120 may operate to perform the communication with the TOF sensor based on the second designated communication speed (e.g., SPI speed=approximately 19 MHZ) in the second state of the PLL of the TOF sensor (e.g., PLL=ON) in response to the changed operation setting of the TOF sensor. For example, the processor 120 may control the TOF sensor to operate in the second designated communication speed (e.g., SPI speed=approximately 19 MHz) and the second state of the PLL (e.g., PLL=ON) according to the setting in the change of the TOF sensor.

When the camera is used, the TOF sensor may always be activated (or turned-on) and may occupy a large portion of current consumption. For example, the TOF sensor may more accurately calculate the timing within the TOF sensor by using the PLL in addition to an oscillator (e.g., a fast oscillator) inside the TOF sensor to emit a designated signal (e.g., the vertical-cavity surface-emitting laser (VCSEL)) at a pulse having a period of approximately 2 ns. In general, the TOF sensor operates to emit the designated signal (e.g., the VCSEL) for only approximately 5 ms out of a period of approximately 15 ms in order to reduce the current consumption, and the PLL may also be turned-off during the corresponding time to reduce the current consumption. When the camera is in operation, the TOF sensor may communicate by increasing the SPI communication speed (e.g., increasing to approximately 19 MHz) in order to reduce the operation occupancy time of the TOF sensor in a specific scenario (or capturing mode). When the TOF sensor communicates at the increased SPI communication speed, the data corruption may occur. In order to solve this problem, the PLL may be turned-on and operate even during a blanking time when the designated signal (e.g., VCSEL) is not emitted, thereby consuming additional current. According to an embodiment, the blanking time may represent a period during which the designated signal is not emitted.

According to an embodiment of the disclosure, when the resolution of the TOF sensor increases (e.g., the increase in the amount of data) or the occupancy rate of the processor 120 by the camera increases, and/or when the processor 120 has high usage (e.g., the amount of calculation processing) and thus it is determined that the processing speed of the TOF sensor should increase, the SPI communication speed may increase to process the data processing speed quickly.

According to another embodiment, when the SPI communication speed of the TOF sensor increases, if the PLL of the TOF sensor is not turned-on, the possibility of data errors may increase. Accordingly, in the embodiment of the disclosure, it is determined whether to control (e.g., on) the PLL as the SPI communication speed increases based on the presence or absence of the data error, and the PLL may be controlled based on the result of the determination. The embodiment is described under the assumption that the SPI communication speed is approximately 3 MHz and approximately 19 MHz, but the disclosure is not limited to (or fixed to) the SPI communication speed disclosed, and may be adaptively (or continuously) changed, if necessary. According to an embodiment, the operation of controlling the state of the PLL of the TOF sensor is not determined based on the SPI communication speed, and the PLL may be set to be turned-on when the data error occurs or when the SPI communication speed is faster than or equal to a specific speed at which the data error is likely to occur.

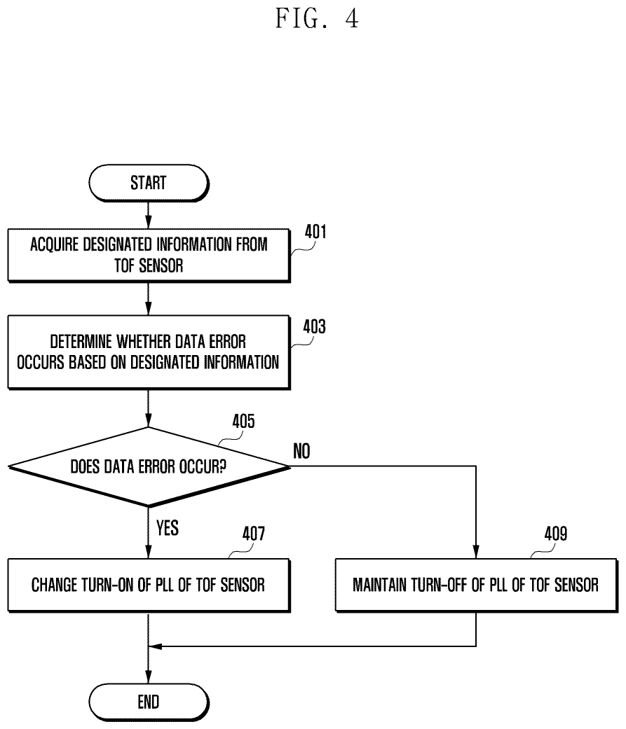

FIG. 4 is a flowchart illustrating the method for operating an electronic device according to an embodiment of the disclosure.

According to an embodiment, FIG. 4 may illustrate an example of a method for supporting the low power mode (e.g., the operation mode for supporting the reduction in current consumption) of the TOF sensor 290 when capturing an image including depth information (e.g., an operation (e.g., a 3D image capturing function) based on a linkage between the TOF sensor 290 of FIG. 2 and the camera module 180 of FIG. 1 or 2) in the electronic device (e.g., the electronic device 101 of FIG. 1 or 2) according to an embodiment.

In the electronic device 101 according to an embodiment of the disclosure, the method of supporting the low power mode operation may be performed, for example, according to the flowchart illustrated in FIG. 4. The flowchart illustrated in FIG. 4 is merely a flowchart according to an embodiment of the operation of the electronic device 101, and the order of at least some operations may be changed or performed in parallel, performed as an independent operation, or at least some other operations may be performed complementarily to at least some operations. According to an embodiment of the disclosure, operations 401 to 409 may be performed in at least one processor (e.g., the processor 120 of FIG. 1 or 2) of the electronic device 101.

The operations described in FIG. 4 may be performed heuristically, for example, by combining with the operations described in FIG. 3, or may be performed heuristically as detailed operations of at least some of the operations described.

As illustrated in FIG. 4, the operation method performed by the electronic device 101 according to an embodiment may include an operation 401 of acquiring the designated information from the TOF sensor (e.g., the TOF sensor 290 of FIG. 2), operations 403 and 405 of determining whether the data error has occurred based on the designated information, an operation 407 of changing (or switching) the PLL of the TOF sensor to the ON state when determining that the data error has occurred, and an operation 409 of maintaining the PLL of the TOF sensor in the OFF state when determining that the data error has not occurred.

Referring to FIG. 4, in operation 401, the processor 120 of the electronic device 101 may perform an operation of acquiring the designated information from the TOF sensor. According to an embodiment, when detecting the operation (or activation) of the TOF sensor, the processor 120 may receive prearranged information with the TOF sensor from the TOF sensor in order to determine the turn-on/off control of the PLL of the TOF sensor. In another embodiment, the prearranged information indicates unique information related to the TOF sensor, and may include, for example, the device identifier (e.g., chip ID) and/or the firmware identifier (e.g., FW ID). According to an embodiment, the prearranged information is not limited to the device identifier and/or the firmware identifier, and may utilize various values (e.g., values written to the TOF sensor (e.g., chip)) predefined between the processor 120 and the TOF sensor so that the processor 120 may determine the validity (or data error) of the TOF sensor.

The device identifier (e.g., chip ID) may indicate a unique value of the TOF sensor written by a manufacturer (or vendor) of the TOF sensor, and may vary for each manufacturer. According to an embodiment, the firmware identifier (e.g., FW ID) may indicate a software version of the TOF sensor.

In operations 403 and 405, the processor 120 may perform an operation of determining whether the data error has occurred based on the designated information. According to an embodiment, the processor 120 may determine whether the data error has occurred by comparing the information received from the TOF sensor with the information related to the TOF sensor pre-stored in the memory (e.g., memory 130 of FIG. 1 or 2) of the electronic device 101. According to another embodiment, the processor 120 may determine that the data error has not occurred when the received information corresponds to the stored information (e.g., normal data) based on the comparison result. According to an embodiment, the processor 120 may determine that the data error has occurred when the received information does not correspond to the stored information (e.g., abnormal data) based on the comparison result.

In operation 405, when the processor 120 determines that the data error has occurred (e.g., ‘Yes’ of operation 405), in operation 407, the processor 120 may perform an operation of changing (or switching) the PLL of the TOF sensor to the ON state.

In operation 405, when the processor 120 determines that the data error has not occurred (e.g., ‘No’ in operation 405), in operation 409, the processor 120 may perform an operation of maintaining the OFF state of the PLL of the TOF sensor.

According to an embodiment of the disclosure, the processor 120 may operate to determine whether to control the PLL based on designated one of various methods or a combination of various methods. According to another embodiment, the processor 120 may determine whether to turn-on/off the PLL based on the SPI communication speed. The processor 120 may determine whether to perform normal data communication with the TOF sensor based on the prearranged information with the TOF sensor, and may determine whether to turn-on/off the PLL based on the result.

According to an embodiment, when the processor 120 increases the SPI communication speed to reduce the occupancy rate of the TOF sensor, the processor 120 may determine the validity of the information and determine whether to turn-on/off the PLL based on the result. According to an embodiment, the processor 120 may periodically perform an additional operation of reading and validating the designated information (e.g., device identifier and/or firmware identifier) of the TOF sensor after validating the first data acquired from the TOF sensor to determine whether to turn-on/off the PLL.

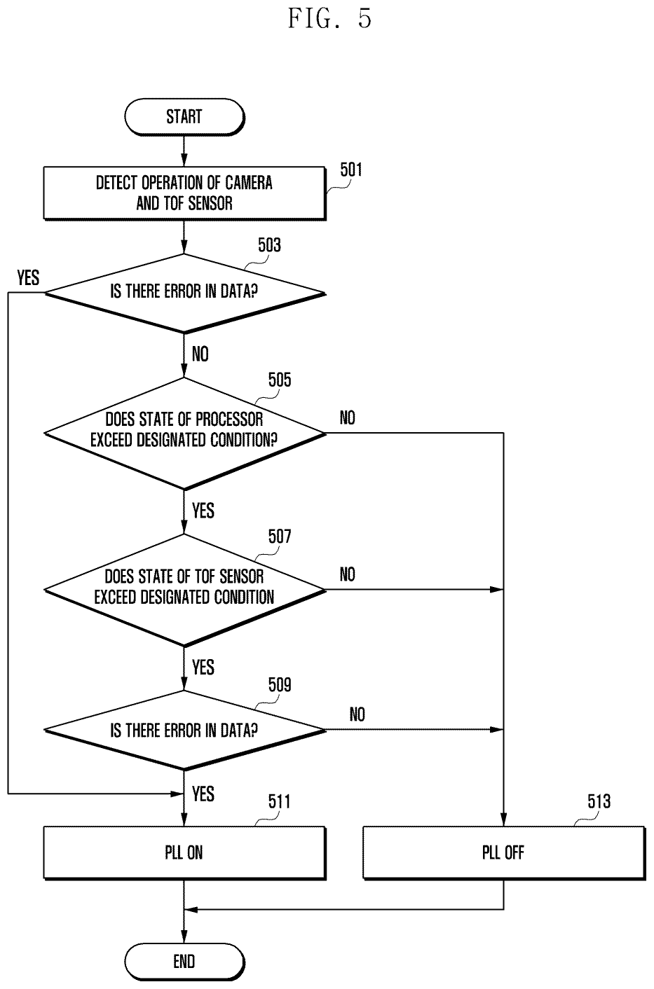

FIG. 5 is a flowchart illustrating the method for operating an electronic device according to an embodiment of the disclosure.

According to an embodiment, FIG. 5 may represent an example of supporting the method for operating the low power mode (e.g., the operating mode for supporting the reduction in current consumption) of the TOF sensor 290 when capturing the image including the depth information (e.g., the operation (e.g., a 3D image capturing function) based on the linkage between the TOF sensor 290 of FIG. 2 and the camera module 180 of FIG. 1 or 2) in the electronic device (e.g., the electronic device 101 of FIG. 1 or 2) according to an embodiment.

In the electronic device 101 according to an embodiment of the disclosure, the method of supporting the low power mode operation may be performed, for example, according to the flowchart illustrated in FIG. 5. The flowchart illustrated in FIG. 5 is merely a flowchart according to an embodiment of the operation of the electronic device 101, and the order of at least some operations may be changed or performed in parallel, performed as an independent operation, or at least some other operations may be performed complementarily to at least some operations. According to an embodiment of the disclosure, operations 501 to 513 may be performed in at least one processor (e.g., the processor 120 of FIG. 1 or 2) of the electronic device 101.

The operations described in FIG. 5 may be performed heuristically, for example, by combining with the operations described in FIGS. 3 and 4, or may be performed heuristically as detailed operations of at least some of the operations described.

As illustrated in FIG. 5, the operation method performed by the electronic device 101 according to an embodiment may include an operation 501 of detecting the operation of the camera and the TOF sensor, an operation 503 of determining whether the data error has occurred, an operation 511 of controlling the PLL to be turned-on when determining that the data error has occurred, an operation 505 of determining whether the state of the processor 120 exceeds the first designated condition when determining that the data error has not occurred, an operation 513 of controlling the PLL to be turned-off when determining that the first designated condition is not exceeded, an operation 507 of determining whether the state of the TOF sensor exceeds the second designated condition when determining that the first designated condition is exceeded, an operation 513 of controlling the PLL to be turned-off when determining that the second designated condition is not exceeded, an operation 509 of determining whether the data error has occurred when determining that the second designated condition is exceeded, an operation 511 of controlling the PLL to be turned-on when determining that the data error has occurred, and an operation 513 of controlling the PLL to be turned-off when determining that the data error has not occurred.

Referring to FIG. 5, in operation 501, the processor 120 of the electronic device 101 may perform an operation of detecting the operation (e.g., execution) of the camera (e.g., the camera module 180 of FIG. 1 or 2) and the TOF sensor (e.g., the TOF sensor 290 of FIG. 2). According to another embodiment, the processor 120 may execute the application (e.g., the camera application) based on the user input. According to an embodiment, the processor 120 may execute (or activate or turn-on) the camera based on the execution of the application. The processor 120 may control the display module (e.g., the display module 160 of FIG. 1 or 2) to display the image (e.g., the preview image) acquired through the camera.

According to an embodiment, the processor 120 may execute (or activate or turn-on) the TOF sensor in response to the execution of the camera. According to an embodiment, the processor 120 may execute the TOF sensor in response to the entry of the designated capturing mode (e.g., the image capturing mode including the depth information) among the capturing modes (or scenarios) performed using the camera. The processor 120 may execute the TOF sensor based on the default setting of the TOF sensor when executing the camera and the TOF sensor. For example, the processor 120 may control the TOF sensor to operate at the first designated communication speed (e.g., SPI speed=approximately 3 MHz) and the first state of the PLL (e.g., PLL=OFF) according to the default setting for the TOF sensor.

In operation 503, the processor 120 may perform an operation of determining whether the data error has occurred. According to an embodiment, the processor 120 may determine whether the data error has occurred based on data such as a parity bit or dummy data.

In operation 503, when the processor 120 determines that the data error has occurred (e.g., ‘Yes’ in operation 503), in operation 511, the processor 120 may perform an operation of controlling the PLL to be turned-on. In an embodiment, the processor 120 may change the default setting (e.g., SPI speed=approximately 3 MHz and PLL=OFF) of the TOF sensor to the designated setting (e.g., SPI speed=approximately 19 MHz and PLL=ON). For example, the processor 120 may control the TOF sensor to operate by determining the change in the SPI communication speed from the first designated communication speed (e.g., SPI speed=approximately 3 MHz) to the second designated communication speed (e.g., SPI speed=approximately 19 MHz) in order to reduce the occupancy time of the TOF sensor, and changing the first state of the PLL (e.g., PLL=OFF) to the second state (e.g., PLL=ON) in order to prevent the data corruption that may occur due to the communication based on the second designated communication speed.

In operation 503, when the processor 120 determines that the data error has not occurred (e.g., ‘No’ in operation 503), in operation 505, the processor 120 may perform an operation of determining whether the state of the processor 120 exceeds the first designated condition. In an embodiment, the first designated condition may include a condition related to performance degradation due to the occupancy rate and/or heat generation (e.g., AP temperature) of the processor 120 (e.g., AP). According to an embodiment, the processor 120 may determine that the data error has occurred when it determines that the occupancy rate of the processor 120 is greater than or equal to the designated occupancy rate (e.g., AP occupancy rate≥approximately 80%) and performance degradation due to the heat generation (e.g., AP temperature≥approximately 50° C.) occurs.

In an embodiment, the processor 120 may determine that the data error is likely to occur when the increase in the SPI communication speed occurs due to the performance degradation. According to an embodiment, the processor 120 may increase the frequency of checking for the data error when the increase in the SPI communication speed occurs due to the performance degradation.

In operation 505, when the processor 120 determines that the first designated condition is not exceeded (e.g., ‘No’ in operation 505), in operation 513, the processor 120 may perform an operation of controlling the PLL to be turned-off. According to an embodiment, the processor 120 may control the TOF sensor to operate according to the default setting (e.g., maintaining the first designated communication speed (e.g., SPI speed=approximately 3 MHZ) and the first state of the PLL (e.g., PLL=OFF)) of the TOF sensor.

In operation 505, when the processor 120 determines that the first designated condition is exceeded (e.g., ‘Yes’ in operation 505), in operation 507, the processor 120 may perform an operation of determining whether the state of the TOF sensor exceeds the second designated condition. According to an embodiment, the second designated condition may include the condition related to the data zone (e.g., TOF data zone or TOF zone) of the TOF sensor. When the processor 120 determines that the setting related to the data zone and/or the operation period of the TOF sensor are greater than or equal to the designated criterion (e.g., TOF data zone≥approximately 1000 pieces) and the operation period exceeds the designated operation period (e.g., operation period>approximately 15 MHZ), the processor 120 may determine that the data error has occurred.

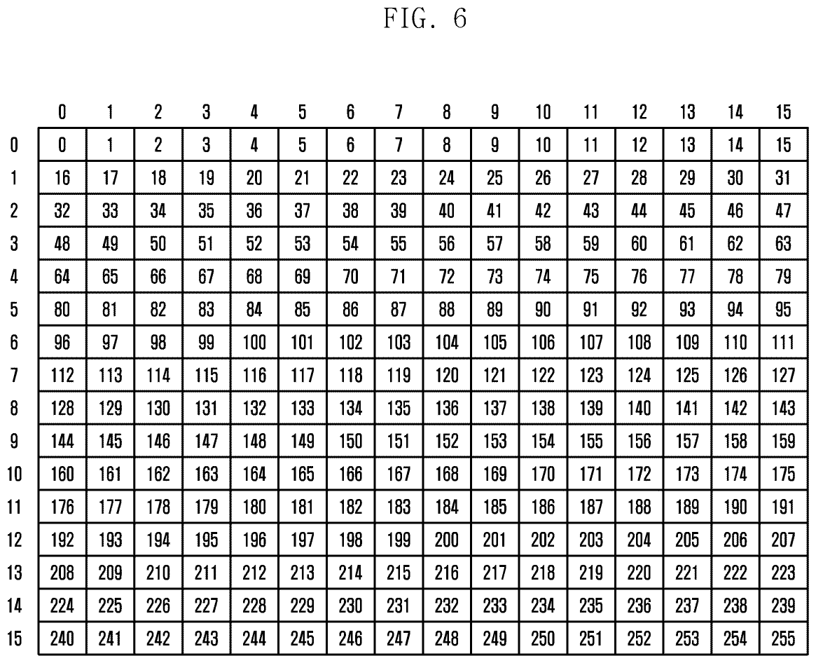

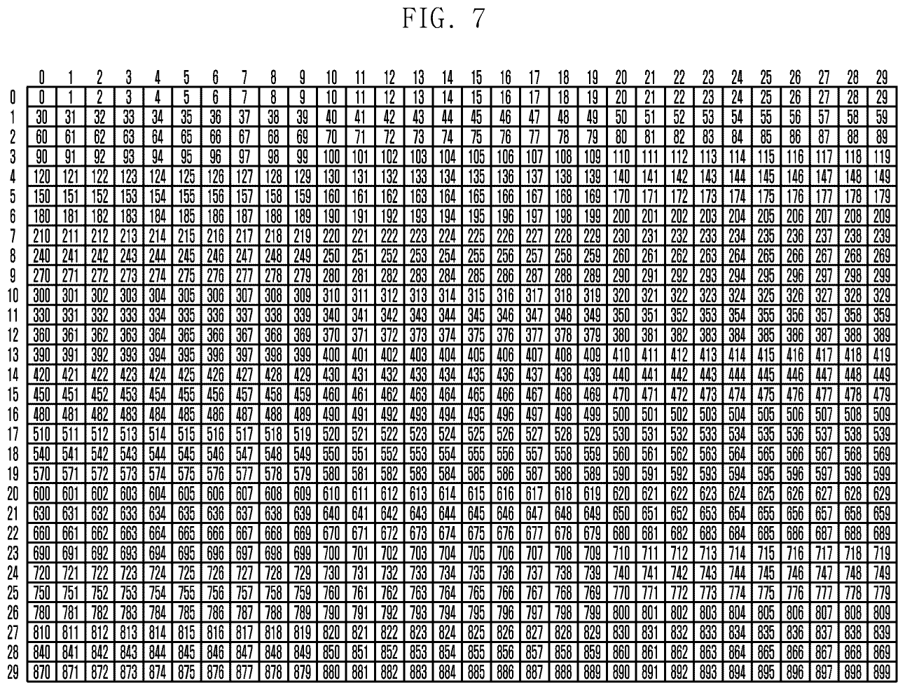

When a frequency higher than or equal to the designated clock (CLK) speed is used for communication, the occurrence rate of the data error may be high. Accordingly, a clock speed at which the data error is likely to occur is designated, and the processor 120 may operate to determine that the data error has occurred when a clock speed higher than or equal to the designated clock speed occurs. According to an embodiment, the processor 120 may increase the frequency of checking the data error when the occurrence rate of the data error increases. According to an embodiment, the data zone of the TOF sensor is exemplified in FIGS. 6 and 7.

In operation 507, when the processor 120 determines that the second designated condition is not exceeded (e.g., ‘No’ in operation 507), in operation 513, the processor 120 may perform an operation of controlling the PLL to be turned-off. According to another embodiment, the processor 120 may control the TOF sensor to operate according to the default setting (e.g., maintaining the first designated communication speed (e.g., SPI speed=approximately 3 MHz) and the first state of the PLL (e.g., PLL=OFF)) of the TOF sensor.

In operation 507, when the processor 120 determines that the second designated condition is exceeded (e.g., ‘Yes’ in operation 507), in operation 509, an operation of determining whether the data error has occurred may be performed. According to an embodiment, the processor 120 may determine whether the data error has occurred based on data such as a parity bit or dummy data.

In operation 509, when the processor 120 determines that the data error has occurred (e.g., ‘Yes’ in operation 509), in operation 511, the processor 120 may perform an operation of controlling the PLL to be turned-on. According to another embodiment, the processor 120 may change the default setting (e.g., SPI speed=approximately 3 MHz and PLL=OFF) of the TOF sensor to the designated setting (e.g., SPI speed=approximately 19 MHz and PLL=ON). For example, the processor 120 may control the TOF sensor to operate by determining the change in the SPI communication speed from the first designated communication speed (e.g., SPI speed=approximately 3 MHz) to the second designated communication speed (e.g., SPI speed=approximately 19 MHz) in order to reduce the occupancy time of the TOF sensor, and changing the first state of the PLL (e.g., PLL=OFF) to the second state (e.g., PLL=ON) in order to prevent the data corruption that may occur due to the communication based on the second designated communication speed.

In operation 509, when the processor 120 determines that the data error has not occurred (e.g., ‘No’ in operation 509), in operation 513, the processor 120 may perform an operation of controlling the PLL to be turned-off. According to an embodiment, the processor 120 may control the TOF sensor to operate according to the default setting (e.g., maintaining the first designated communication speed (e.g., SPI speed=approximately 3 MHZ) and the first state of the PLL (e.g., PLL=OFF)) of the TOF sensor.

According to an embodiment of the disclosure, the electronic device 101 may confirm the number of data zones (e.g., TOF data zone or TOF zone) of the TOF sensor when the occupancy rate of the processor 120 is approximately 80% or more and the heat generation (e.g., AP temperature) is approximately 50° C. or higher. The electronic device 101 may control the SPI communication speed to reduce the AP occupancy rate based on the number of data zones. For example, when the electronic device 101 uses a function of consuming a lot of current according to the capturing mode (or scenario) of the camera, if it is determined that the occupancy rate of the processor 120 (e.g., AP) exceeds approximately 80%, the electronic device 101 may operate to change the SPI communication speed. In an embodiment, examples of current consumption for each capturing mode of the camera and the SPI communication speed adjustment according to the current consumption are exemplified in <Table 1>. In an embodiment, the examples exemplified in <Table 1> are disclosed to help understanding of the description, and are not limited to the examples mentioned in <Table 1>, and variations of the examples and/or other examples not mentioned may be included.

TABLE 1

| | | Communication |
|---|---|---|
| Capturing Mode | Performance (Current) | Speed |
| Front video UHD30 | Approximately 91% | Communication |
| Front video FHD60 | Approximately 92% | speed of |
| Front photo default | Approximately 93% | approximately |
| Rear video FHD30 (W) | Approximately 93% | 3 MHz |
| Front video UHD60 | Approximately 98% | |
| Night mode | Approximately 98% | |
| Preview Zoom in/out | Approximately 99% | |
| Photo Default ×0.5 | Approximately 100% | |
| Rear video UHD30 (W) | Approximately 105% | Communication |
| Photo Default ×1 | Approximately 105% | speed of |
| Rear video FHD30 (W) (Dual view) | Approximately 109% | approximately |
| Capturing magnification switching | Approximately 109% | 19 MHz or more |
| Portrait Video (Character) | Approximately 111% | |
| Rear video UHD60 (W) | Approximately 116% | |
| Photo Default ×1 (Dual preview) | Approximately 124% | |
| Rear video UHD30 (W) (Dual view) | Approximately 125% | |
| Video Slow motion | Approximately 151% | |
| Video single take | Approximately 158% | |
| Video Super slow motion | Approximately 162% | |

According to an embodiment, Table 1 may show an example of current consumption by the capturing mode of the camera (e.g., the camera module 180 of FIG. 1 or 2). According to an embodiment, Table 1 may show an example of increasing the communication speed of the TOF sensor and relatively reducing the occupancy rate of the processor 120 by increasing the occupancy rate (e.g., the AP occupancy rate) of the processor (e.g., the processor 120 of FIG. 1 or 2) during the operation of the camera. According to another embodiment, as exemplified in Table 1, the current consumption value may show various examples of rates measured based on various capturing modes. According to an embodiment, the electronic device 101 may adjust (e.g., increase) the communication speed based on various rates, and reduce the occupancy rate (e.g., the AP occupancy rate) of the processor 120 accordingly.

According to yet another embodiment, the electronic device 101 may reduce the current consumption of the TOF sensor in proportion to the increase in current consumption due to the camera. According to an embodiment, the electronic device 101 may determine whether the data error has occurred in order to reduce the current consumption in the TOF sensor, and control (e.g., on/off control) the PLL of the TOF sensor based on whether the data error has occurred. According to an embodiment, the electronic device 101 may operate by changing the SPI communication speed according to the necessity of the change in the occupancy rate of the processor 120 due to the switching of the capturing mode of the camera. For example, as exemplified in Table 1, the electronic device 101 may determine the necessity of reducing the occupancy rate of the processor 120 in various capturing modes of the camera, determine that the data error has occurred due to the change in the SPI communication speed, and dynamically determine whether to control the on/off of the PLL to reduce the current.

When it is necessary to maintain the communication speed of each capturing mode of the camera quickly, the electronic device 101 may operate to turn-on the PLL, and operate to determine that the data error has occurred due to the communication between the TOF sensor and the processor 120 in order to reduce the current consumption. According to an embodiment, the electronic device 101 may verify the integrity of the values of data transmitted through the communication between the TOF sensor and the processor 120 based on various methods. For example, a checksum may be used as a method of verifying the integrity.

According to an embodiment, the electronic device 101 may detect an error using the checksum for the depth data of approximately 64 zones of the TOF sensor. In another embodiment, the electronic device 101 may determine that there is no error when the checksum value for the depth data of 64 zones calculated by the TOF sensor and the checksum value calculated by the processor 120 match. According to an embodiment, the electronic device 101 may determine that a bit error has occurred when the checksum values do not match, and may operate to control the PLL to be turned-on.

The electronic device 101 may control to change the communication speed based on the amount of data to be transmitted according to the zone operation of the TOF sensor. For example, the electronic device 101 may operate by reducing the number of zones operating according to the depth, such as approximately 64 or approximately 100 zones, in order to reduce the amount of data in the TOF sensor that operates approximately 1,000 zones. However, when the number of zones operating by the TOF sensor may not be reduced depending on the capturing mode (e.g., 3D application) used in the camera, the SPI communication speed may be quickly changed to reduce the occupancy rate of the TOF sensor. According to an embodiment, it is possible to determine whether the data error has occurred when the SPI communication speed is changed, and to turn-on the PLL to operate when determining that the data error has occurred. Examples of this are illustrated in FIGS. 6 and 7.

FIGS. 6 and 7 are diagrams illustrating examples of variably operating the data zone of the TOF sensor according to various embodiments of the disclosure.

According to an embodiment, FIG. 6 may illustrate an example in which the TOF sensor operates approximately 256 zones (or data zones) (e.g., zones 0 to 255). According to an embodiment, FIG. 7 may illustrate an example in which the TOF sensor operates approximately 900 zones (e.g., zones 0 to 899). According to another embodiment, assuming the TOF sensor operating approximately 900 zones, the electronic device 101 can operate by reducing the number of zones to approximately 256 or approximately 64 zones when a depth of a subject is close or when precise operation is not required for the 3D application. For example, a large difference in current consumption may occur depending on the number of zones operating. For example, when reading data from approximately 900 zones simultaneously, the data that needs to be transmitted may increase as the number of zones increases depending on the type of data received from each zone, such as distance, peak signal, maxrange, temperature, ambient, and/or confidence level.

The electronic device 101 may have the increased calculation time, and may operate to reduce the occupancy rate by increasing the SPI communication speed. According to an embodiment, assuming that the calculation amount of data accounts for approximately 80% or more of the performance of the processor 120 during the camera operation and applications using current in the background account for approximately 10% of the performance of the processor 120, the electronic device 101 should use the remaining approximately 10% of the performance of the processor 120 to operate the TOF sensor and perform its various other functions. Therefore, when the SPI communication speed is slowed down, the occupancy time of the processor 120 increases, resulting in the problems with the camera operation performance.

When the performance of the camera in the electronic device 101 should be used maximally, the SPI communication speed may be adjusted (e.g., increased) to the designated communication speed (e.g., approximately 19 MHz) to reduce the occupancy rate of the TOF sensor, and at the same time, the PLL of the TOF sensor may operate to be turned-on to prevent the occurrence of the data error. According to an embodiment, an example of power reduction values according to the on/off of the PLL is exemplified in Table 2.

TABLE 2

| Integration | PLL | | Current |
|---|---|---|---|
| Time (ms) | ON (mW) | OFF (mW) | OFF/ON ratio |
| Approximately 5 | Approximately 112.7 | Approximately 84.3 | Approximately 75% |
| Approximately 6 | Approximately 122.5 | Approximately 96.3 | Approximately 79% |
| Approximately 7 | Approximately 132.3 | Approximately 108.2 | Approximately 82% |
| Approximately 8 | Approximately 144.1 | Approximately 120.1 | Approximately 83% |
| Approximately 9 | Approximately 153.9 | Approximately 132.1 | Approximately 86% |
| Approximately 10 | Approximately 162 | Approximately 144 | Approximately 89% |
| Approximately 11 | Approximately 172.5 | Approximately 155.9 | Approximately 90% |
| Approximately 12 | Approximately 185.1 | Approximately 167.9 | Approximately 91% |
| Approximately 13 | Approximately 195.6 | Approximately 179.8 | Approximately 92% |
| Approximately 14 | Approximately 206.1 | Approximately 191.7 | Approximately 93% |
| Approximately 15 | Approximately 214.7 | Approximately 203.7 | Approximately 95% |

According to an embodiment, Table 2 may represent an example of the power reduction values according to the on/off of the PLL. In an embodiment, the examples exemplified in Table 2 are disclosed to help understanding of the description, and are not limited to the examples mentioned in Table 2, and variations of the examples and/or other examples not mentioned may be included.

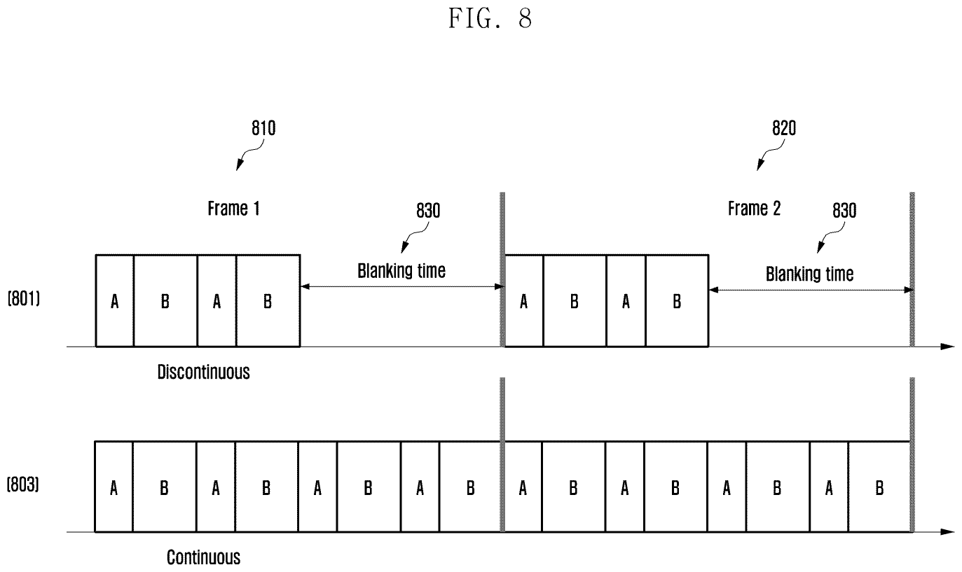

According to an embodiment, as exemplified in Table 2, when the TOF sensor turns off the PLL during the blanking time, a current difference of approximately 25% may occur until the integration time reaches approximately 5 ms. According to an embodiment, the blanking time may represent a period during which the VCSEL is not emitted in the TOF sensor. According to an embodiment, the integration time may represent the period during which the VCSEL is emitted in the TOF sensor. According to an embodiment, the current may be reduced by reducing the integration time while the PLL is turned-on and when the PLL is turned-off during the blanking time, an additional current of approximately 25% may be reduced based on approximately 5 ms. According to an embodiment, the low power mode for reducing the current by reducing the VCSEL emission time is illustrated in FIG. 8.

FIG. 8 is a diagram illustrating an example of operating the low power mode that reduces a current by reducing the VCSEL emission time of the TOF sensor according to an embodiment of the disclosure.

Referring to FIG. 8, an interval of frame interval 810 may represent a first frame (frame 1) interval, and an interval of frame interval 820 may represent a second frame (frame 2) interval. According to an embodiment, an example of element <801> may represent an example of a discontinuous operation of the TOF sensor according to the operation method of the disclosure, and an example of element <803> may represent an example of a continuous operation of the TOF sensor according to the conventional operation method in the TOF sensor. According to an embodiment, in the example of element <801>, element <803> may represent the blanking time interval. According to an embodiment, in the example of element <801> and element <803>, an interval including ‘A’ and ‘B’ may represent the integration time interval. According to an embodiment, ‘A’ and ‘B’ may represent an example of the signal (e.g., VCSEL) that the TOF sensor generates in the integration time interval for each frame interval 810 and 820.

Referring to FIG. 8, in the case of the conventional operation method of the TOF sensor, such as the example of element <803>, the PLL is turned-on even in the blanking time interval 830 to consume current, whereas in the case of the operation method of the TOF sensor according to the disclosure, such as the example of element <801>, when the VCSEL is not emitted in the blanking time interval 830, the PLL may be turned-off to reduce the current consumption.

According to an embodiment, when the TOF sensor operates by turning-off the PLL in the blanking time interval 830, for example, when the SPI communication is performed at a high communication speed, the data corruption may occur, and thus, a situation may arise where the PLL should be turned-on. For example, when the sensor communication is performed at a communication speed of approximately 19 MHz, the data corruption may occur, thereby making normal communication impossible. According to an embodiment of the disclosure, it is possible to prevent the data corruption due to the increase in the communication speed, and reduce the current consumption at the same time.

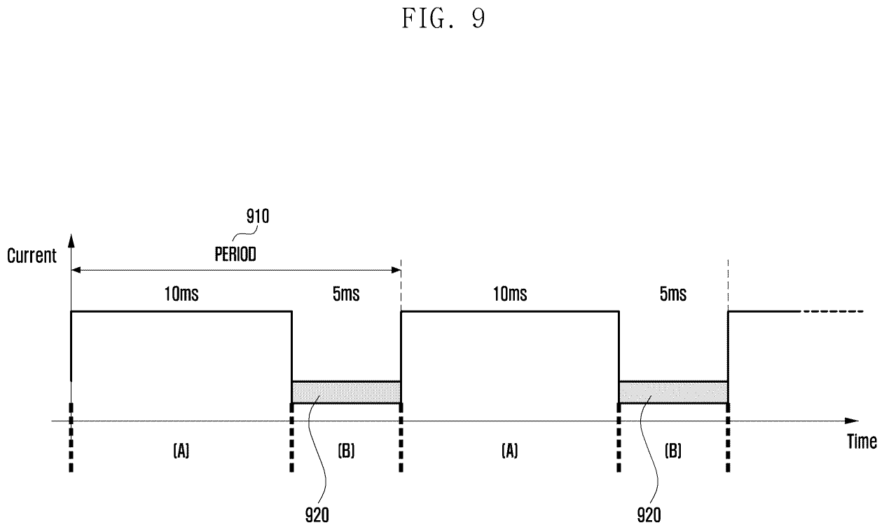

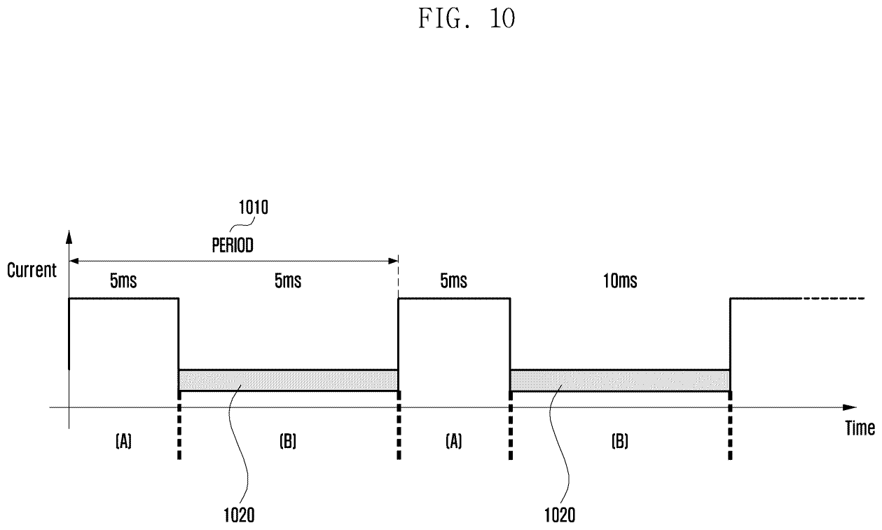

When the electronic device 101 maximizes the performance of the camera, for example, when the occupancy time of the processor 120 of the TOF sensor should be reduced, the electronic device 101 may operate by turning-on the PLL. For example, in the case of the capturing mode (or scenario) such as general photography, the electronic device 101 may reduce the SPI communication speed to the low speed (for example, approximately 3 MHz or less) and turn-off the PLL to reduce the current consumption. Examples of this are illustrated in FIGS. 9 and 10.

FIGS. 9 and 10 are diagrams illustrating examples of the current reduction difference according to the turn-off of the PLL for each integration time of the TOF sensor according to various embodiments of the disclosure.

According to an embodiment, FIGS. 9 and 10 may illustrate examples of the current difference according to the turn-on/off of the PLL according to the integration time setting. According to an embodiment, in FIGS. 9 and 10, an X-axis may represent a time, and a Y-axis may represent a current. According to an embodiment, the integration time may represent the interval in which the VCSEL is turned-on, and the interval in which the VCSEL is turned-off may represent the blanking time. For example, periods 910 and 1010 in FIGS. 9 and 10 may represent an operation period of the TOF sensor, and may include the operations of the turn-on/off of the VCSEL and the turn-on/off of the PLL for each operation period. According to an embodiment, the element (A) interval may operate as VCSEL=ON and PLL=ON as the integration time interval. According to an embodiment, the element (B) interval may operate as VCSEL=OFF and PLL=ON as the blanking time interval. According to an embodiment, hatched portions 920 and 1020 of the element (B) interval in FIGS. 9 and 10 may represent the current difference when switching PLL=ON to PLL=OFF in the blanking time interval.

Referring to FIGS. 9 and 10, as the integration time during one period 910 becomes shorter (e.g., approximately 10 ms->approximately 5 ms), the interval in which the PLL may be turned-off may increase (e.g., approximately 10 ms->approximately 5 ms), and the rate at which the current consumption may be reduced may increase.

According to an embodiment, when the SPI communication speed is fast for the high-performance operation of the camera, the electronic device 101 turns-on the PLL during the blanking time interval to prevent the communication problems, and in the case of the non-high-performance operation of the camera, even if the occupancy rate of the processor 120 of the TOF sensor relatively increases, the current consumption may be reduced by operating with a combination of the low-speed communication (e.g., the communication of approximately 3 MHz or less) and the PLL=OFF.

According to another embodiment, in the examples of FIGS. 9 and 10, VCSEL=ON is expressed as being emitted for approximately 5 ms or approximately 10 ms, but in order to measure the actual depth more precisely than a ‘cm’ unit, a light period may be set to a ‘ns’ level. In this case, the control period of the VCSEL may require a control period of at least approximately 500 MHz or more, and a general level of OSC may not generate a clock (CLK) of approximately 500 MHz or more. For example, it may be difficult to accurately match the clock between the VCSEL emission period and the SPI communication. Therefore, according to the embodiment of the disclosure, by branching the frequency through the PLL, the VCSEL may be made to generate a pulse of approximately 2 ns, thereby more accurately matching the clock between the VCSEL emission period and the SPI communication.

According to an embodiment of the disclosure, the operation method performed by the electronic device 101 may include an operation of detecting the operations of the camera module and the time of flight (TOF) sensor. The operation method may include an operation of identifying at least one designated condition associated with setting the operation of the TOF sensor. The operation method may include an operation of determining whether to change the setting of the TOF sensor based on the designated condition. The operation method may include an operation of performing the communication with the TOF sensor based on the first designated communication speed corresponding to a default setting when it is determined that the setting is not changed. The operation method may include an operation of changing the setting of the TOF sensor from the default setting to the designated setting when it is determined that the setting is changed. The operation method may include an operation of performing the communication with the TOF sensor based on the second designated communication speed adjusted in response to the change in the setting.

The operation of detecting the operation of the TOF sensor may include an operation of executing the TOF sensor when the camera module is executed or in response to the entry of the capturing mode designated for the camera module.

According to an embodiment, the operation of performing the communication with the TOF sensor based on the first designated communication speed may include an operation of controlling the TOF sensor to operate at the first designated communication speed and in the first state of the phase locked loop (PLL) based on the default setting of the TOF sensor.

According to an embodiment, the operation of determining whether to change the setting of the TOF sensor may include an operation of determining at least one designated condition related to the PLL control of the TOF sensor.

The at least one designated condition includes the condition in which the data error occurs due to the serial communication according to the occupancy rate of the processor, the amount of data according to the change in the data zone of the TOF sensor, the temperature of the processor, and/or the capturing mode of the camera module.

According to an embodiment, the operation of determining whether to change the setting of the TOF sensor may include an operation of determining to change the setting of the TOF sensor when the operation state of the electronic device corresponding to the at least one designated condition is identified.

According to another embodiment, the operation of changing to the designated setting includes an operation of controlling the TOF sensor to operate at a second designated communication speed faster than the first designated communication speed and in the second state of a PLL when determining the change in the setting of the TOF sensor.

According to an embodiment, the operation of controlling the TOF sensor includes an operation of controlling the TOF sensor to operate by changing the first state (PLL=OFF) of the PLL to the second state (PLL=ON) in order to prevent the data corruption that may occur due to the communication based on the second designated communication speed.

According to an embodiment, the operation of determining whether to change the setting of the TOF sensor may include an operation of determining whether to control the PLL based on whether the data error occurs due to the serial communication.

According to yet another embodiment, the operation of determining whether to change the setting of the TOF sensor may include an operation of acquiring the designated information from the TOF sensor when detecting the operation of the TOF sensor, an operation of determining whether the data error occurs based on the designated information, and an operation of changing the PLL of the TOF sensor to the ON state based on determining that the data error occurs.

According to an embodiment, the designated information may represent the unique information related to the TOF sensor and may include the device identifier (device ID) and/or the firmware identifier (firmware ID).

The electronic device according to various embodiments may be one of various types of electronic devices. The electronic devices may include, for example, a portable communication device (e.g., a smartphone), a computer device, a portable multimedia device, a portable medical device, a camera, a wearable device, or a home appliance. According to an embodiment of the disclosure, the electronic devices are not limited to those described above.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wiredly), wirelessly, or via a third element.

As used in connection with various embodiments of the disclosure, the term “module” may include a unit implemented in hardware, software, or firmware, and may interchangeably be used with other terms, for example, “logic,” “logic block,” “part,” or “circuitry”. A module may be a single integral component, or a minimum unit or part thereof, adapted to perform one or more functions. For example, according to an embodiment, the module may be implemented in a form of an application-specific integrated circuit (ASIC).

Various embodiments as set forth herein may be implemented as software (e.g., the program 140) including one or more instructions that are stored in a storage medium (e.g., internal memory 136 or external memory 138) that is readable by a machine (e.g., the electronic device 101). For example, a processor (e.g., the processor 120) of the machine (e.g., the electronic device 101) may invoke at least one of the one or more instructions stored in the storage medium, and execute it, with or without using one or more other components under the control of the processor. This allows the machine to be operated to perform at least one function according to the at least one instruction invoked. The one or more instructions may include a code generated by a complier or a code executable by an interpreter. The machine-readable storage medium may be provided in the form of a non-transitory storage medium. Wherein, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

According to an embodiment, a method according to various embodiments of the disclosure may be included and provided in a computer program product. The computer program product may be traded as a product between a seller and a buyer. The computer program product may be distributed in the form of a machine-readable storage medium (e.g., compact disc read only memory (CD-ROM)), or be distributed (e.g., downloaded or uploaded) online via an application store (e.g., PlayStore™), or between two user devices (e.g., smart phones) directly. If distributed online, at least part of the computer program product may be temporarily generated or at least temporarily stored in the machine-readable storage medium, such as memory of the manufacturer's server, a server of the application store, or a relay server.

According to various embodiments, each component (e.g., a module or a program) of the above-described components may include a single entity or multiple entities, and some of the multiple entities may be separately disposed in different components. According to various embodiments, one or more of the above-described components may be omitted, or one or more other components may be added. Alternatively or additionally, a plurality of components (e.g., modules or programs) may be integrated into a single component. In such a case, according to various embodiments, the integrated component may still perform one or more functions of each of the plurality of components in the same or similar manner as they are performed by a corresponding one of the plurality of components before the integration. According to various embodiments, operations performed by the module, the program, or another component may be carried out sequentially, in parallel, repeatedly, or heuristically, or one or more of the operations may be executed in a different order or omitted, or one or more other operations may be added.

It will be appreciated that various embodiments of the disclosure according to the claims and description in the specification can be realized in the form of hardware, software or a combination of hardware and software.

Any such software may be stored in non-transitory computer readable storage media. The non-transitory computer readable storage media store one or more computer programs (software modules), the one or more computer programs include computer-executable instructions that, when executed by one or more processors of an electronic device individually or collectively, cause the electronic device to perform a method of the disclosure.

Any such software may be stored in the form of volatile or non-volatile storage such as, for example, a storage device like read only memory (ROM), whether erasable or rewritable or not, or in the form of memory such as, for example, random access memory (RAM), memory chips, device or integrated circuits or on an optically or magnetically readable medium such as, for example, a compact disk (CD), digital versatile disc (DVD), magnetic disk or magnetic tape or the like. It will be appreciated that the storage devices and storage media are various embodiments of non-transitory machine-readable storage that are suitable for storing a computer program or computer programs comprising instructions that, when executed, implement various embodiments of the disclosure. Accordingly, various embodiments provide a program comprising code for implementing apparatus or a method as claimed in any one of the claims of this specification and a non-transitory machine-readable storage storing such a program.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a camera module including a plurality of cameras;
a time of flight (TOF) sensor;
memory, comprising one or more storage media, storing instructions; and
one or more processors communicatively coupled to the camera module, the TOF sensor, and the memory,
wherein the instructions, when executed by the one or more processors individually or collectively, cause the electronic device to:
detect operations of the camera module and the TOF sensor,
identify at least one designated condition associated with setting an operation of the TOF sensor,
determine whether to change the setting of the TOF sensor based on the designated condition,
perform communication with the TOF sensor based on a first designated communication speed corresponding to a default setting when it is determined that the setting is not changed,
change the setting of the TOF sensor from the default setting to a designated setting when it is determined that the setting is changed, and
perform communication with the TOF sensor based on a second designated communication speed adjusted in response to the change in the setting.

2. The electronic device of claim 1, wherein the instructions, when executed by the one or more processors individually or collectively, further cause the electronic device to execute the TOF sensor when the camera module is executed or in response to an entry of a capturing mode designated for the camera module.

3. The electronic device of claim 1, wherein the TOF sensor includes:
a vertical-cavity surface-emitting laser (VCSEL) driver that emits a VCSEL that emits light to detect an object; and
a phase locked loop (PLL) that controls the VCSEL emission in the TOF sensor to operate at a designated synchronous timing and prevents a communication error in serial communication between the TOF sensor and the processor.

4. The electronic device of claim 1, wherein the instructions, when executed by the one or more processors individually or collectively, further cause the electronic device to control the TOF sensor to operate at the first designated communication speed and in a first state of a phase locked loop (PLL) based on the default setting of the TOF sensor.

5. The electronic device of claim 1,
wherein the instructions, when executed by the one or more processors individually or collectively, further cause the electronic device to:
determine at least one designated condition related to PLL control of the TOF sensor, and
determine the change in the setting of the TOF sensor when an operating state of the electronic device corresponding to the at least one designated condition is identified, and
wherein the at least one designated condition includes a condition in which a data error occurs in serial communication according to an occupancy rate of the processor, an amount of data according to a change in a data zone of the TOF sensor, a temperature of the processor, and/or a capturing mode of the camera module.

6. The electronic device of claim 1, wherein the instructions, when executed by the one or more processors individually or collectively, further cause the electronic device to control the TOF sensor to operate at the second designated communication speed faster than the first designated communication speed and in a second state of a PLL when determining the change in the setting of the TOF sensor.

7. The electronic device of claim 6, wherein the instructions, when executed by the one or more processors individually or collectively, further cause the electronic device to control the TOF sensor to operate by changing a first state of the PLL to the second state in order to prevent data corruption that occurs due to communication based on the second designated communication speed.

8. The electronic device of claim 1, wherein the instructions, when executed by the one or more processors individually or collectively, further cause the electronic device to determine whether to control a PLL based on whether a data error occurs due to serial communication.

9. The electronic device of claim 1,
wherein the instructions, when executed by the one or more processors individually or collectively, further cause the electronic device to:
acquire designated information from the TOF sensor when detecting the operation of the TOF sensor,
determine whether a data error occurs based on the designated information, and
change a PLL of the TOF sensor to an ON state based on determining an occurrence of the data error,
wherein the designated information includes unique information related to the TOF sensor, and
wherein the unique information includes a device identifier (device ID) and/or a firmware identifier (firmware ID).

10. A method for operating an electronic device, the method comprising:
detecting operations of a camera module and a time of flight (TOF) sensor;
identifying at least one designated condition associated with setting an operation of the TOF sensor;
determining whether to change the setting of the TOF sensor based on the designated condition;
performing communication with the TOF sensor based on a first designated communication speed corresponding to a default setting when it is determined that the setting is not changed;
changing the setting of the TOF sensor from the default setting to a designated setting when it is determined that the setting is changed; and
performing communication with the TOF sensor based on a second designated communication speed adjusted in response to the change in the setting.

11. The method of claim 10, further comprising:
executing the TOF sensor when the camera module is executed or in response to an entry of a capturing mode designated for the camera module.

12. The method of claim 10, wherein the TOF sensor includes:
a vertical-cavity surface-emitting laser (VCSEL) driver that emits a VCSEL that emits light to detect an object, and
a phase locked loop (PLL) that controls the VCSEL emission in the TOF sensor to operate at a designated synchronous timing and prevents a communication error in serial communication between the TOF sensor and one or more processors.

13. The method of claim 10, wherein the performing of the communication with the TOF sensor based on the first designated communication speed includes controlling the TOF sensor to operate at the first designated communication speed and in a first state of a phase locked loop (PLL) based on the default setting of the TOF sensor.

14. The method of claim 10,
wherein the determining of whether to change the setting of the TOF sensor includes:
determining the at least one designated condition related to PLL control of the TOF sensor, and
determining the change in the setting of the TOF sensor when an operating state of the electronic device corresponding to the at least one designated condition is identified, and
wherein the at least one designated condition includes a condition in which a data error occurs in serial communication according to an occupancy rate of one or more processors, an amount of data according to a change in a data zone of the TOF sensor, a temperature of the one or more processors, and/or a capturing mode of the camera module.

15. The method of claim 10, wherein the changing to the designated setting includes controlling the TOF sensor to operate at the second designated communication speed faster than the first designated communication speed and in a second state of a PLL when determining the change in the setting of the TOF sensor.

16. The method of claim 15, wherein the controlling of the TOF sensor includes controlling the TOF sensor to operate by changing a first state of the PLL to the second state in order to prevent data corruption that occurs due to communication based on the second designated communication speed.

17. The method of claim 10, further comprising:
determining whether to control a PLL based on whether a data error occurs due to serial communication.

18. The method of claim 13, further comprising:
acquiring designated information from the TOF sensor when detecting the operation of the TOF sensor,
determining whether a data error occurs based on the designated information, and
changing a PLL of the TOF sensor to an ON state based on determining an occurrence of the data error,
wherein the designated information includes unique information related to the TOF sensor, and
wherein the unique information includes a device identifier (device ID) and/or a firmware identifier (firmware ID).

19. One or more non-transitory computer-readable storage media storing one or more computer programs including computer-executable instructions that, when executed by one or more processors of an electronic device individually or collectively, cause the electronic device to perform operations, the operations comprising:
detecting operations of a camera module and a time of flight (TOF) sensor;
identifying at least one designated condition associated with setting an operation of the TOF sensor;
determining whether to change the setting of the TOF sensor based on the designated condition;
performing communication with the TOF sensor based on a first designated communication speed corresponding to a default setting when it is determined that the setting is not changed;
changing the setting of the TOF sensor from the default setting to a designated setting when it is determined that the setting is changed; and
performing communication with the TOF sensor based on a second designated communication speed adjusted in response to the change in the setting.

20. The one or more non-transitory computer-readable storage media of claim 19, wherein the performing of the communication with the TOF sensor based on the first designated communication speed includes controlling the TOF sensor to operate at the first designated communication speed and in a first state of a phase locked loop (PLL) based on the default setting of the TOF sensor.
